(19) United States
(12) Patent Application Publication
(10) Pub. No.: US 2025/0081854 A1
(43) Pub. Date: Mar. 6, 2025

(54) PIEZOELECTRIC MATERIAL COMPOSITION, METHOD OF MANUFACTURING THE SAME,PIEZOELECTRIC DEVICE, AND APPARATUS INCLUDING THE PIEZOELECTRIC DEVICE

(71) Applicants: LG Display Co., Ltd., Seoul (KR); Korea University Research and Business Foundation, Seoul (KR)

(72) Inventors: Sungwook KO, Paju-si (KR); SeungRyull PARK, Paju-si (KR); Sahn NAHM, Seoul (KR); Jungsoo KIM, Seoul (KR); Geun-Soo LEE, Seoul (KR); Eunji KIM, Seoul (KR)

(73) Assignees: LG Display Co., Ltd., Seoul (KR); Korea University Research and Business Foundation, Seoul (KR)

(21) Appl. No.: 18/807,701

(22) Filed: Aug. 16, 2024

(30) Foreign Application Priority Data
Aug. 31, 2023 (KR) 10-2023-0115727

(51) Int. Cl. H10N 30/853; C04B 35/468; C04B 35/64; H10N 30/092; H10N 30/097

(52) U.S. Cl. CPC H10N 30/8536; C04B 35/4684; C04B 35/64; H10N 30/092; H10N 30/097; H10N 30/8554

(57) ABSTRACT

A piezoelectric material composition may be represented by Equation 1. A piezoelectric device may include a piezoelectric device layer including the piezoelectric material composition represented by Equation 1, a first electrode disposed at a first surface of the piezoelectric device layer, and a second electrode disposed at a second surface different from the first surface of the piezoelectric device layer.

$${a PbZrO}_{3} - {b PbTiO}_{3} - ( 1 - a - b ) Pb ( {Ni}_{c} {Nb}_{1 - c} ) {O}_{3} + x mol \% A + y vol \% {BaTiO}_{3} \qquad [ Equation 1 ]$$

where A is Fe₂O₃, Co₂O₃, Mn₂O₃, ZnO, GeO₂, CuO, or NiO, and 0.15≤a≤0.24, 0.29≤b≤0.38, 0.30≤c≤0.35, 0.00≤x≤3.00, and 0.00≤y≤7.00.

### CROSS-REFERENCE TO RELATED APPLICATION

This application claims the benefit of and the priority to the Korean Patent Application No. 10-2023-0115727, filed on Aug. 31, 2023 in the Korean Intellectual Property Office, the disclosure of which is hereby incorporated by reference in its entirety.

### BACKGROUND

### 1. Technical Field

The present disclosure relates to a piezoelectric material composition, a method of manufacturing the same, a piezoelectric device, and an apparatus including the piezoelectric device.

### 2. Discussion of the Related Art

Piezoelectric device including piezoelectric materials are being widely used in ultrasound vibrators, transducers, and actuators in the field of ultrasound apparatuses, image apparatuses, sound apparatuses, communication apparatuses, and sensors.

### SUMMARY

The inventors have recognized the following problems occurring when a developed piezoelectric material is practically applied.

Piezoelectric devices including a piezoelectric material are capable of being miniaturized and are higher in vibration efficiency than a dynamic speaker using a coil, and thus, may be applied to display apparatuses such as televisions (TVs) including a light emitting display apparatus.

Therefore, materials having a high piezoelectric characteristic are desired for applying a sound apparatus, including a piezoelectric device, to a display apparatus or an apparatus.

An object of the present disclosure is directed to providing a piezoelectric material composition which may have a high piezoelectric characteristic.

An object of the present disclosure is directed to providing a method of manufacturing a piezoelectric material composition, which may orient grains of a piezoelectric material by using a template so as to provide a piezoelectric material composition having a high piezoelectric characteristic, thereby enhancing a piezoelectric characteristic.

An object of the present disclosure is directed to providing a piezoelectric device having a desirable piezoelectric characteristic and an apparatus including the piezoelectric device.

An object of the present disclosure is directed to providing a piezoelectric device, having a composition of various combinations for developing a material where two or more crystal structures are provided in a room temperature, and a piezoelectric device including a material having an enhanced piezoelectric characteristic.

Additional features, advantages, and aspects of the present disclosure will be set forth in the description that follows, and in part will also be apparent from the description, or may be learned by practice of the inventive concepts provided herein. Other features, advantages, and aspects of the present disclosure may be realized and attained by the structure particularly pointed out in the written description, or derivable therefrom, and the claims hereof as well as the appended drawings.

To achieve these and other advantages and in accordance with objects of the disclosure, as embodied and broadly described herein, a piezoelectric material composition according to an aspect of the present disclosure may be represented by Equation 1.

$${a PbZrO}_{3} - {b PbTiO}_{3} - ( 1 - a - b ) Pb ( {Ni}_{c} {Nb}_{1 - c} ) {O}_{3} + x mol \% A + y vol \% {BaTiO}_{3} \qquad [ Equation 1 ]$$

where A is Fe₂O₃, Co₂O₃, Mn₂O₃, ZnO, GeO₂, CuO, or NiO, and 0.15≤a≤0.24, 0.29≤b≤0.38, 0.30≤c≤0.35, 0.00≤x≤3.00, and 0.00≤y≤7.00.

In another aspect of the present disclosure, a method of manufacturing a piezoelectric material composition may comprise mixing a matrix material with a seed material to prepare a slurry, molding the slurry to prepare a green tape, and sintering the green tape to prepare a sinter that includes the piezoelectric material composition. The piezoelectric material composition may be represented by Equation 1.

$${a PbZrO}_{3} - {b PbTiO}_{3} - ( 1 - a - b ) Pb ( {Ni}_{c} {Nb}_{1 - c} ) {O}_{3} + x mol \% A + y vol \% {BaTiO}_{3} \qquad [ Equation 1 ]$$

where A is Fe₂O₃, Co₂O₃, Mn₂O₃, ZnO, GeO₂, CuO, or NiO, and 0.15≤a≤0.24, 0.29≤b≤0.38, 0.30≤c≤0.35, 0.00≤x≤3.00, and 0.00≤y≤7.00.

In yet another aspect of the present disclosure, a piezoelectric device may comprise a piezoelectric device layer including a piezoelectric material composition including a first material and a second material surrounded by the first material, a first electrode disposed at a first surface of the piezoelectric device layer, and a second electrode disposed at a second surface different from the first surface of the piezoelectric device layer. The piezoelectric material composition may be represented by Equation 1.

$${a PbZrO}_{3} - {b PbTiO}_{3} - ( 1 - a - b ) Pb ( {Ni}_{c} {Nb}_{1 - c} ) {O}_{3} + x mol \% A + y vol \% {BaTiO}_{3} \qquad [ Equation 1 ]$$

where A is Fe₂O₃, Co₂O₃, Mn₂O₃, ZnO, GeO₂, CuO, or NiO, and 0.15≤a≤0.24, 0.29≤b≤0.38, 0.30≤c≤0.35, 0.00≤x≤3.00, and 0.00≤y≤7.00.

In still another aspect of the present disclosure, an apparatus may comprise a vibration member, and the piezoelectric device disposed at a rear surface of the vibration member. The piezoelectric device may comprise a piezoelectric device layer including a first material and a second material surrounded by the first material, a first electrode disposed at a first surface of the piezoelectric device layer, and a second electrode disposed at a second surface different from the first surface of the piezoelectric device layer. The piezoelectric device layer may be represented by Equation 1.

$${a PbZrO}_{3} - {b PbTiO}_{3} - ( 1 - a - b ) Pb ( {Ni}_{c} {Nb}_{1 - c} ) {O}_{3} + x mol \% A + y vol \% {BaTiO}_{3} \qquad [ Equation 1 ]$$

where A is Fe₂O₃, Co₂O₃, Mn₂O₃, ZnO, GeO₂, CuO, or NiO, and 0.15≤a≤0.24, 0.29≤b≤0.38, 0.30≤c≤0.35, 0.00≤x≤3.00, and 0.00≤y≤7.00.

According to some example embodiments of the present disclosure, a piezoelectric material composition having a desirable piezoelectric characteristic, a piezoelectric device including the piezoelectric material composition, and an apparatus including the piezoelectric device may be provided.

According to some example embodiments of the present disclosure, because a piezoelectric material composition has a desirable piezoelectric characteristic, a piezoelectric device and an apparatus each including the piezoelectric material composition may be driven with a low driving voltage.

According to some example embodiments of the present disclosure, a method of manufacturing a piezoelectric material composition may be capable of low temperature sintering, and thus, may be considerably reduced in time and cost for manufacturing a piezoelectric device, thereby considerably enhancing a productivity of the piezoelectric device.

According to some example embodiments of the present disclosure, a productivity may be enhanced, and thus, an optimization of a manufacturing process may be implemented.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on the claims. Further objects and advantages are discussed below in conjunction with aspects and example embodiments of the disclosure.

It is to be understood that both the foregoing description and the following detailed description of the present disclosure are merely by way of example and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this disclosure, illustrate embodiments of the disclosure and together with the description serve to explain principles of the disclosure.

FIG. 1 is a illustrates a cross-sectional view of a piezoelectric device according to an example embodiment of the present disclosure.

FIG. 2 illustrates a method of manufacturing a piezoelectric device according to an example embodiment of the present disclosure.

FIG. 3 illustrates a method of manufacturing a matrix material of a piezoelectric material composition according to an example embodiment of the present disclosure.

FIG. 4 illustrates a method of manufacturing a seed material of a piezoelectric material composition according to an example embodiment of the present disclosure.

FIG. 5 illustrates a grain variation occurring in a step of preparing a tertiary seed according to the example embodiment illustrated in FIG. 4.

FIGS. 6A to 6C are each a scanning electron microscope (SEM) image and show the grain variation occurring in the step of preparing the tertiary seed according to the example embodiment illustrated in FIG. 5.

FIG. 7 is a graph showing X-ray diffraction patterns with respect to a CuO content of a piezoelectric material composition according to an example embodiment of the present disclosure.

FIG. 8 is a graph showing a relative density (%), a dielectric constant ε^{T}₃₃/ε₀, a loss factor tan δ, a piezoelectric charge constant d₃₃, and an electromechanical coupling factor k_{ρ} with respect to a CuO content of a piezoelectric material composition according to an example embodiment of the present disclosure.

FIGS. 9A to 9D each illustrates an X-ray diffractometer (XRD) pattern of a seed content of a piezoelectric material composition according to an example embodiment of the present disclosure.

FIGS. 10A to 10D each illustrates an XRD pattern of a seed content of a piezoelectric material composition according to another example embodiment of the present disclosure.

FIGS. 11A to 11D each illustrates an XRD pattern of a seed content of a piezoelectric material composition according to another example embodiment of the present disclosure.

FIGS. 12A to 12D each illustrates an XRD pattern of a seed content of a piezoelectric material composition according to another example embodiment of the present disclosure.

FIG. 13 is a graph showing the Lotgering factor with respect to a BaTiO₃ content and a sintering temperature of a piezoelectric material composition according to an example embodiment of the present disclosure.

FIG. 14 is a graph showing a relative density (%), a piezoelectric charge constant d₃₃ (pC/N), an electromechanical coupling factor k_{ρ}, a dielectric constant ε^{T}₃₃/ε₀, and a loss factor tan δ with respect to a sintering temperature of a piezoelectric material composition according to an example embodiment of the present disclosure.

FIG. 15 illustrates an automotive sound apparatus according to an example embodiment of the present disclosure.

FIG. 16 illustrates a perspective view of a display apparatus according to an example embodiment of the present disclosure.

FIG. 17 illustrates a cross-sectional view taken along line I-I′ in FIG. 16 according to an example embodiment of the present disclosure.

FIG. 18 illustrates a piezoelectric device in the example embodiment illustrated in FIG. 16 according to an example embodiment of the present disclosure.

Throughout the drawings and the detailed description, unless otherwise described, the same drawing reference numerals should be understood to refer to the same or like parts. The sizes, lengths, and thicknesses of layers, regions and elements, and depiction of thereof may be exaggerated for clarity, illustration, and/or convenience.

### DETAILED DESCRIPTION

Reference is now made in detail to some of the example embodiments of the present disclosure illustrated in the accompanying drawings. In the following description, where a detailed description of relevant known steps, methods, functions, structures, or configurations may unnecessarily obscure features of the present disclosure, a detailed description of such known steps, methods, functions, structures, or configurations may be omitted. The progression of processing steps and/or operations described may be a non-limiting example.

The sequence of steps and/or operations may not be limited to that set forth herein and may be changed to occur in an order that is different from an order described herein, with the exception of steps and/or operations desirably occurring in a particular order. In one or more examples, two operations in succession may be performed substantially concurrently, or the two operations may be performed in a reverse order or in a different order depending on a function or operation involved.

Advantages and features of the present disclosure, and implementation methods thereof, are clarified through the example embodiments described with reference to the accompanying drawings. The present disclosure may, however, be embodied in different forms and should not be construed as limited to the various example embodiments set forth herein. Rather, these example embodiments are examples and are provided so that this disclosure may be thorough and complete to assist those skilled in the art to understand the inventive concepts without limiting the protected scope of the present disclosure.

Shapes, dimensions (e.g., sizes, lengths, widths, heights, thicknesses, locations, radii, diameters, and areas), proportions, ratios, angles, numbers, the number of elements, and the like disclosed herein, including those illustrated in the drawings, are merely examples, and thus, the present disclosure is not limited to the illustrated details. Any example embodiment described herein as an “example” is not to be construed as preferred or advantageous over other example embodiments. It is, however, noted that the relative dimensions of the components illustrated in the drawings are part of the present disclosure.

In the specification, where the terms “comprise,” “have,” “include,” “contain,” “constitute,” “made of,” “formed of,” or the like are used, one or more other elements may be added unless the term, such as “only”, is used. The terms used in the present disclosure are merely used to describe various example embodiments, and are not intended to limit the scope of the present disclosure. The terms of a singular form may include a plurality of elements, and vice versa, unless the context clearly indicates otherwise.

Embodiments are example embodiments. Aspects are example aspects. “Aspects,” “examples,” and the like should not be construed as preferred or advantageous over other example embodiments. An aspect, an example, an example embodiment, or the like may refer to one or more aspects, one or more examples, one or more example embodiments, or the like, unless stated otherwise. Further, the term “may” encompasses all the meanings of the term “can.”

In construing an element or numerical value, unless explicitly stated otherwise, the element or the numerical value is construed to include an error or tolerance range even where no explicit description of such an error or tolerance range is provided. An error or tolerance range may be caused by various factors (e.g., process factors, internal or external impact, noise, or the like). In interpreting a numerical value, the value is interpreted as including an error range unless explicitly stated otherwise.

In describing a positional relationship, when the positional relationship between two parts (e.g., layers, films, regions, components, sections, or the like) is described, for example, using “on,” “upon,” “on top of,” “over,” “under,” “above,” “below,” “beneath,” “near,” “close to,” “adjacent to,” “beside,” “next to,” “at or on a side of,” or the like, one or more other parts may be located between the two parts unless a more limiting term, such as “immediate(ly),” “direct(ly),” or “close(ly),” is used. For example, where a structure is described as being positioned “on,” upon,” “on top of,” “over,” “under,” “above,” “below,” “beneath,” “near,” “close to,” “adjacent to,” “beside,” “next to,” “at or on a side of,” or the like another structure, this description should be construed as including a case in which the structures contact each other as well as a case in which one or more additional structures are disposed or interposed therebetween. Furthermore, the terms “front,” “rear,” “back,” “left,” “right,” “top,” “bottom,” “downward,” “upward,” “upper,” “lower,” “up,” “down,” “column,” “row,” “vertical,” “horizontal,” and the like refer to an arbitrary frame of reference.

Spatially relative terms, such as “below,” “beneath,” “lower,” “on,” “above,” “upper” and the like, can be used to describe a correlation between various elements (e.g., layers, films, regions, components, sections, or the like) as shown in the drawings. The spatially relative terms are to be understood as terms including different orientations of the elements in use or in operation in addition to the orientation depicted in the drawings. For example, if the elements shown in the drawings are turned over, elements described as “below” or “beneath” other elements would be oriented “above” other elements. Thus, the term “below,” which is an example term, can include all directions of “above” and “below.” Likewise, a term “above” or “on” can include both directions of “above” and “below.”

In describing a temporal relationship, when the temporal order is described as, for example, “after,” “subsequent,” “next,” “before,” “preceding,” “prior to,” or the like, a case that is not consecutive or not sequential may be included and thus one or more other events may occur therebetween, unless a more limiting term, such as “just,” “immediate(ly),” or “direct(ly),” is used.

It is understood that, although the terms “first,” “second,” or the like may be used herein to describe various elements (e.g., layers, films, regions, components, sections, or the like), these elements should not be limited by these terms, for example, to any particular order, precedence, or number of elements. These terms are used only to distinguish one element from another. For example, a first element could be termed as a second element, and, similarly, a second element could be termed as a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element and the like) are not limited by ordinal numbers or the names in front of the elements. Further, a first element may include one or more first elements. Similarly, a second element or the like may include one or more second elements or the like.

In describing elements of the present disclosure, the terms “first,” “second,” “A,” “B,” “(a),” “(b),” or the like may be used. These terms are intended to identify the corresponding element(s) from the other element(s), and these are not used to define the essence, sequence, basis, order, or number of the elements.

For the expression that an element (e.g., layer, film, region, component, section, or the like) is described as “connected,” “coupled,” “attached,” “adhered,” or the like to another element, the element may not only be directly connected, coupled, attached, adhered, or the like to another element, but may also be indirectly connected, coupled, attached, adhered, or the like to another element with one or more intervening elements or layers disposed or interposed between the elements, unless otherwise specified.

For the expression that an element (e.g., layer, film, region, component, section, or the like) “contacts,” “overlaps,” or the like with another element, the element may not only directly contact, overlap, or the like with another element, but may also indirectly contact, overlap, or the like with another element with one or more intervening elements disposed or interposed between the elements, unless otherwise specified.

An expression such as “at least one of” when preceding a list of elements may modify the entire list of elements and may not modify the individual elements of the list. The term “at least one” should be understood as including any and all combinations of one or more of the elements of the list. For example, each of the phrases of “at least one of a first item, a second item, or a third item” and “at least one of a first item, a second item, and a third item” may represent (i) a combination of items provided by one or more of the first item, the second item, and the third item or (ii) only one of the first item, the second item, and the third item. The meaning of “at least one of a first element, a second element, and a third element” encompasses the combination of all three listed elements, combinations of any two of the three elements, as well as each individual element, the first element, the second element, and the third element.

The expression of a first element, a second elements “and/of” a third element should be understood to encompass one of the first, second and third elements, as well as any and all combinations of the first, second, and third elements. By way of example, A, B and/or C encompasses only A; only B; only C; any of A, B, and C (e.g., A, B, or C)); some combinations of A, B, and C (e.g., A and B; A and C; or B and C); and all of A, B, and C. Furthermore, an expression “A/B” may be understood as A and/or B. For example, an expression “A/B” can refer to only A; only B; A or B; or A and B.

In the specification, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element (e.g., layer, film, region, component, sections, or the like) is referred to as being “between” at least two elements, the element may be the only element between the at least two elements, or one or more intervening elements may also be present.

In the specification, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

In the specification, the phrases “one or more among” and “one or more of” may be used interchangeably simply for convenience unless stated otherwise.

Features of various embodiments of the present disclosure may be partially or entirely coupled to or combined with each other, may be technically associated with each other, and may be operated, linked, or driven together in various ways. Features of the present disclosure may be implemented or carried out independently from each other, or may be implemented or carried out together in a co-dependent or related relationship. In one or more aspects, the components of each apparatus according to various example embodiments of the present disclosure may be operatively coupled and configured.

Unless otherwise defined, the terms (including technical and scientific terms) used herein have the same meaning as commonly understood by one of ordinary skill in the art to which the disclosure belongs. It will be further understood that terms, such as those defined in commonly used dictionaries, should be interpreted as having a meaning that is, for example, consistent with their meaning in the context of the relevant art and should not be interpreted in an idealized or overly formal sense, unless expressly defined otherwise herein.

In the following description, various example embodiments of the present disclosure are described in detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings.

In addition, for convenience of description, a scale, dimension, size, and thickness of each of the elements illustrated in the accompanying drawings may be different from an actual scale, dimension, size, and thickness. Thus, example embodiments of the present disclosure are not limited to a scale, dimension, size, and thickness illustrated in the drawings.

The inventors have developed a sintering method of a piezoelectric material composition and a composition of a templated grain growth (TGG) piezoelectric material composition through several experiments, so as to develop a piezoelectric material having a desirable piezoelectric characteristic. For example, TGG may be a process where TGG may be performed with a seed. For example, non-TGG may be a process where a grain growth process may be randomly performed without a seed.

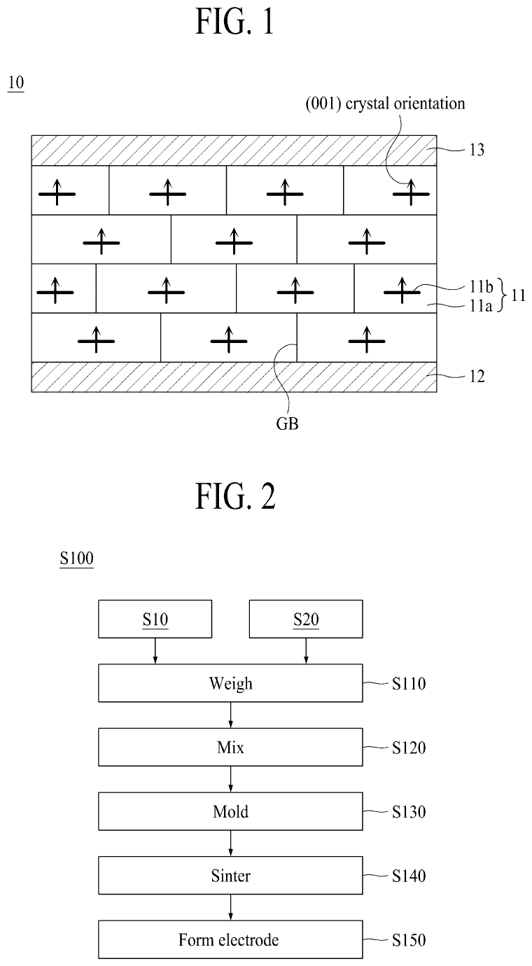

FIG. 1 illustrates a cross-sectional view of a piezoelectric device according to an example embodiment of the present disclosure. This is a cross-sectional view illustrating a piezoelectric device including a piezoelectric material composition manufactured by a TGG process.

Referring to FIG. 1, a piezoelectric device 10 according to an example embodiment of the present disclosure may include a piezoelectric material composition 11, a first electrode layer 12, and a second electrode layer 13.

The piezoelectric material composition 11 may be provided between the first electrode layer 12 and the second electrode layer 13. The piezoelectric material composition 11 may be expressed as the following Equation 1.

$${a PbZrO}_{3} - {b PbTiO}_{3} - ( 1 - a - b ) Pb ( {Ni}_{c} {Nb}_{1 - c} ) {O}_{3} + x mol \% A + y vol \% {BaTiO}_{3} \qquad [ Equation 1 ]$$

where A is Fe₂O₃, Co₂O₃, Mn₂O₃, ZnO, GeO₂, CuO, or NiO, and 0.15≤a≤0.24, 0.29≤b≤0.38, 0.30≤c≤0.35, 0.00≤x≤3.00, and 0.00≤y≤7.00.

The piezoelectric material composition 11 may include a plurality of grains including a first material 11a and a second material 11b. Each of the plurality of grains including the first material 11a and the second material 11b may be divided by a grain boundary GB. The first material 11a may be expressed as the following Equation 2.

$${a PbZrO}_{3} - {b PbTiO}_{3} - ( 1 - a - b ) Pb ( {Ni}_{c} {Nb}_{1 - c} ) {O}_{3} + x mol \% A \qquad [ Equation 2 ]$$

where A is Fe₂O₃, Co₂O₃, Mn₂O₃, ZnO, GeO₂, CuO, or NiO, and 0.15≤a≤0.24, 0.29≤b≤0.38, 0.30≤c≤0.35, and 0.00≤x≤3.00.

A first material 11a may be a material except a second material 11b in Equation 1. For example, the first material 11a may be a material, except BaTiO₃ which is the second material 11b, of Equation 1. For example, Equation 2 may be obtained by removing BaTiO₃, which is a seed material, in Equation 1. For example, the first material 11a may include one of Fe₂O₃, Co₂O₃, Mn₂O₃, ZnO, GeO₂, CuO, and NiO. For example, when the first material 11a includes CuO, CuO may be added to the piezoelectric material composition of Equation 1 at 0 mol % to 3 mol %. For example, CuO may be added to the piezoelectric material composition of Equation 1 at 3 mol % or less. For example, CuO may be added to the piezoelectric material composition of Equation 1 at 1.0 mol %.

Accordingly, some example embodiments of the present disclosure may include CuO, and thus, may further enhance the sinterability of a piezoelectric material.

Moreover, some example embodiments of the present disclosure may include CuO, thereby providing a piezoelectric material composition which may be capable of sintering at a low temperature.

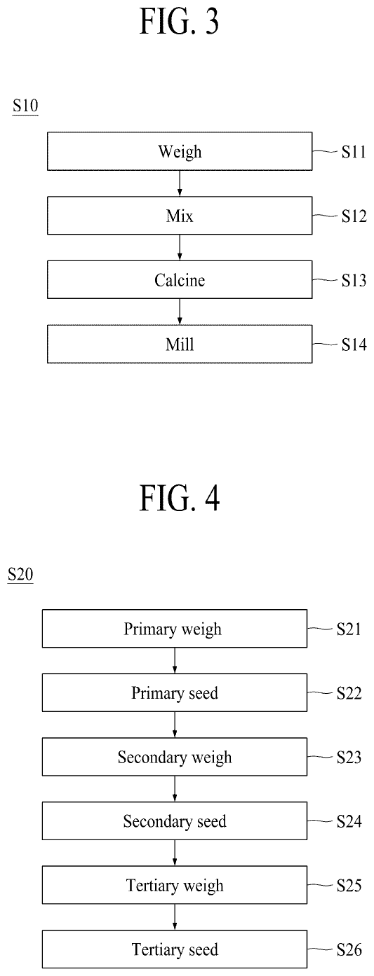

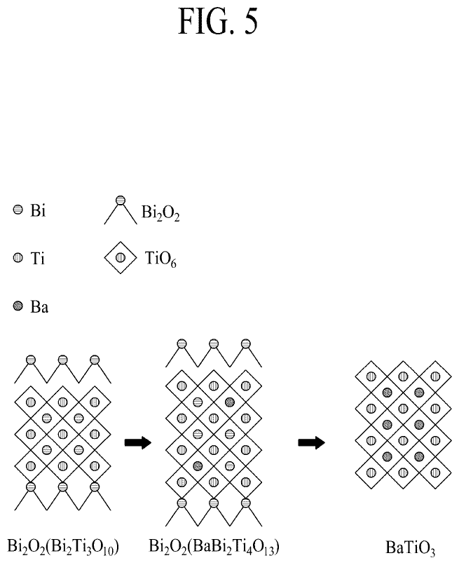

A grain of the first material 11a may be grown based on a crystal orientation of the second material 11b. For example, an aspect ratio of the second material 11b may be 5 to 20. For example, the piezoelectric material composition 11 according to some example embodiments of the present disclosure may include a plurality of first materials 11a. For example, the plurality of first materials 11a may have the same or substantially the same crystal orientation. For example, the plurality of first materials 11a may have a (001) crystal orientation. For example, the plurality of first materials 11a may have a crystal structure which is grown in a (001) orientation. For example, the first material 11a according to some example embodiments of the present disclosure may be configured to surround the second material 11b. The first material 11a according to an example embodiment of the present disclosure may be prepared by a method of preparing a matrix material described below with reference to FIGS. 2 and 3.

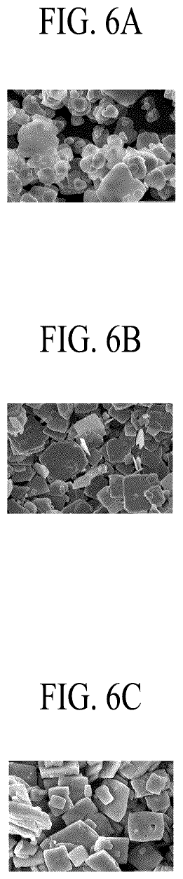

The second material 11b may be formed in the first material 11a. The second material 11b may be surrounded by the first material 11a. The second material 11b may be disposed at a center portion of the first material 11a. For example, the center portion may not numerically and accurately correspond to a center (or middle) in the first material 11a having a certain volume and may be a certain region including a center (or middle) of the first material 11a having a certain volume. For example, the center portion may be a region extending from a center of the first material 11a, in the first material 11a having a certain volume. Therefore, in some example embodiments of the present disclosure, even when the second material 11b is provided at a position deviating from the center (or middle) of the first material 11a, this may be within the scope of the present disclosure. For example, the second material 11b may be disposed in each of the plurality of first materials 11a, and in grain orientation growth, the second material 11b may be provided close to a grain boundary GB which is a boundary between the plurality of first materials 11a. The second material 11b according to some example embodiments of the present disclosure may be a seed material. For example, the second material 11b may include BaTiO₃. For example, BaTiO₃ may be added to the piezoelectric material composition of Equation 1 at 0 mol % to 7 mol %. For example, BaTiO₃ may be added to the piezoelectric material composition of Equation 1 at 7 mol % or less. For example, the second material 11b may function as a template so that the first material 11a may grow in a crystal orientation of the second material 11b, in a sintering process. For example, the first material 11a may be sintered based on a crystal orientation of the second material 11b. Accordingly, crystal orientations of the plurality of first materials 11a may be oriented in the same or substantially the same orientation. The second material 11b according to an example embodiment of the present disclosure may be prepared by a method of preparing a seed material described below with reference to FIGS. 2 and 4.

A first electrode layer 12 and a second electrode layer 13 may be configured to face each with a piezoelectric material composition 11 therebetween. For example, the first electrode layer 12 may be configured at a first surface (or a lower surface) of the piezoelectric material composition 11, and the second electrode layer 13 may be configured at a second surface (or an upper surface) of the piezoelectric material composition 11. The piezoelectric material composition 11 according to some example embodiments of the present disclosure may function as a piezoelectric device 10, based on the first electrode layer 12 and the second electrode layer 13 respectively configured at the first surface (or the lower surface) and the second surface (or the upper surface).

FIG. 2 illustrates a method of manufacturing a piezoelectric device according to an example embodiment of the present disclosure. This may represent a method of manufacturing a piezoelectric device including a piezoelectric material composition according to an example embodiment of the present disclosure with reference to FIG. 1.

Referring to FIG. 2, a method S100 of manufacturing a piezoelectric device including a piezoelectric material composition according to an example embodiment of the present disclosure may include a step S110 of preparing a seed material and a matrix material of a piezoelectric material composition, a step S120 of mixing the matrix material with the seed material to prepare a slurry, a step S130 of molding the slurry to prepare a molding element, a step S140 of sintering the molding element to prepare a sintered material, and a step S150 of forming an electrode in a sintered piezoelectric material composition. The piezoelectric material composition may be expressed as the following Equation 1.

$${a PbZrO}_{3} - {b PbTiO}_{3} - ( 1 - a - b ) Pb ( {Ni}_{c} {Nb}_{1 - c} ) {O}_{3} + x mol \% A + y vol \% {BaTiO}_{3} \qquad [ Equation 1 ]$$

where A is Fe₂O₃, Co₂O₃, Mn₂O₃, ZnO, GeO₂, CuO, or NiO, and 0.15≤a≤0.24, 0.29≤b≤0.38, 0.30≤c≤0.35, 0.00≤x≤3.00, and 0.00≤y≤7.00.

First, in a step S110 of preparing a matrix material and a seed material of a piezoelectric material composition, the matrix material may not include BaTiO₃, which is a seed, in Equation 1 and may be prepared by a method S10 of preparing the matrix material described below. For example, the seed material may have a composition of BaTiO₃ and may have a size of 5 μm or more, but example embodiments of the present disclosure are not limited thereto. For example, the seed may have a value of 5 μm or less, based on a filtering method. An aspect ratio of the seed may be 5 to 40 or 10 to 15. The seed may be prepared by a manufacturing method S20 of the seed described below. For example, the seed material may be added to the piezoelectric material composition of Equation 2 by 7 mol % or less, but example embodiments of the present disclosure are not limited thereto. Accordingly, the step S110 of preparing the matrix material and the seed material of a piezoelectric material composition may be performed.

Subsequently, the method S100 may include the step S120 of mixing the matrix material with the seed material to prepare the slurry. The step S120 of mixing the matrix material with the seed material to prepare the slurry may include preparing the slurry including the matrix material and mixing the seed material with the matrix material.

The step of preparing the slurry including the matrix material may include adding an appropriate amount of dispersant and solvent to the matrix material having a composition of Equation 1. For example, the solvent may include one or more of ethanol, methanol, isopropanol, methyl ethyl ketone (MEK), toluene, and distilled water, but example embodiments of the present disclosure are not limited thereto. By adding an appropriate amount of dispersant and solvent to the matrix material, a slurry where the matrix material is well dispersed in the solvent may be prepared. According to some example embodiments of the present disclosure, a dispersant may decrease the viscosity of a slurry including the matrix material and may be used for dispersing the first material 11a and the second material 11b in a solvent. For example, the step of preparing the slurry may be prepared through a milling step performed four times, but example embodiments of the present disclosure are not limited to the number of milling steps.

For example, primary slurry milling may be performed by adding an appropriate amount of solvent and dispersant to the prepared matrix material slurry. The primary slurry milling may be a ball milling. For example, the primary slurry milling may be performed for 24 hours to 72 hours within a range of 100 rpm to 150 rpm, but example embodiments of the present disclosure are not limited thereto. For example, the primary slurry milling may be performed for 12 hours to 16 hours within a range of 100 rpm to 150 rpm, but example embodiments of the present disclosure are not limited thereto. For example, the primary slurry milling may be a wet milling. For example, the primary slurry milling may be performed for 24 hours to 72 hours within a range of 100 rpm to 150 rpm after matrix powders, a solvent, and a dispersant are added to Nalgene bottle along with nylon or high density polyethylene (HDPE) and a ZrO₂ ball (for example, a YSZ ball), but example embodiments of the present disclosure are not limited thereto.

For example, after the primary slurry milling, secondary slurry milling may be performed by further adding an appropriate amount of a binder and a plasticizer. The secondary slurry milling may be a ball milling. For example, the secondary slurry milling may be performed for 6 hours to 24 hours within a range of 100 rpm to 150 rpm. For example, the secondary slurry milling may be a wet milling. For example, after the binder and the plasticizer are added to the primary slurry milling, the secondary slurry milling may be performed for 6 hours to 25 hours within a range of 100 rpm to 150 rpm along with a ZrO₂ ball (for example, a YSZ ball), but example embodiments of the present disclosure are not limited thereto.

The binder (or a bonding agent or a binding agent) may provide the stiffness, flexibility, ductility, durability, tenacity, and smoothness of a molding element (or green tape). The binder may include at least one of polyvinylbutyral (PVB) resin, polyvinyl alcohol (PVA), and polyethylene glycol (PEG), but example embodiments of the present disclosure are not limited thereto. A binder in the field of piezoelectric material composition may be used.

The plasticizer may be added for providing the elasticity and plastic characteristic of the molding element. The plasticizer may include at least one of phthalate-based plasticizer, adipate-based plasticizer, phosphate-based plasticizer, polyether-based plasticizer, and polyester-based plasticizer. A plasticizer material in the field of piezoelectric material composition may be used.

The step of mixing the seed material with the matrix material may be mixing the seed material with the slurry including the matrix material which is prepared at the previous step and may be performed through a tertiary slurry milling and a quaternary slurry milling. For example, the tertiary slurry milling may be performed at low speed at 20 rpm to 30 rpm for 3 to 6 hours without balls, but example embodiments of the present disclosure are not limited thereto. For example, the milling process may be performed for a short time at a speed which is lower than the primary slurry milling and the secondary slurry milling. For example, the tertiary slurry milling may be performed for 3 hours to 6 hours within a range of 20 rpm to 30 rpm by adding a seed after the ZrO₂ ball is removed, but example embodiments of the present disclosure are not limited thereto.

For example, the quaternary slurry milling may be performed after the tertiary slurry milling. The quaternary slurry milling may be performed through a planetary milling performed three times for 10 minutes within a range of 500 rpm to 2,000 rpm, but example embodiments of the present disclosure are not limited thereto. For example, the quaternary slurry milling may be uniformly distributed a BT seed material (for example, a BT seed (BaTiO₃)). Accordingly, a method of manufacturing a piezoelectric material composition according to some example embodiments of the present disclosure may mix a seed material with a matrix material to be uniformly distributed.

Some example embodiments of the present disclosure may further include an aging step and a degassing step of removing an air bubble and a gas after the quaternary slurry milling.

The degassing step may be or may include adjusting the slurry to have appropriate viscosity for a molding process and removing an air bubble remaining in the slurry, in a below-described step of molding a piezoelectric material. For example, the slurry may be adjusted to have a viscosity of 1,000 cPs to 3,000 cPs (centipoise) by a vacuum stirrer at a room temperature, but example embodiments of the present disclosure are not limited thereto. For example, the slurry may be adjusted to have a viscosity of 1,700 cPs to 2,400 cPs, or 2,000 cPs (centipoise) by a vacuum stirrer at a room temperature, but example embodiments of the present disclosure are not limited thereto. Accordingly, an air bubble may be removed from the slurry, and a viscosity may be adjusted by volatilizing a solvent.

The aging step may be or may include adjusting a temperature of the slurry to a room temperature again because the slurry is cooled when a solvent is volatilized in the degassing step. For example, in the aging step, stirring may be performed for a short time at a low speed of about 10 rpm by the stirrer, but example embodiments of the present disclosure are not limited thereto. Accordingly, a piezoelectric material having a slurry form may be formed.

Subsequently, a step S130 of molding (or press-molding) a slurry to prepare a molding element may include manufacturing the molding element having a certain volume and shape from a slurry (or a piezoelectric material) where the matrix material and the seed material prepared in the step S120 are mixed with each other.

For example, a step of molding the slurry (or the piezoelectric material) to prepare a molding element may include tape-casting a piezoelectric material, performing a primary molding on the tape-casted piezoelectric material, and performing a secondary molding on the primarily-molded piezoelectric material.

The tape casting step may be tape-casting a slurry where the matrix material prepared in the previous step is mixed with a seed material by a tape casting device (or a blade). For example, in a case where tape casting is performed at 90° C. or more, because an evaporation rate of a solvent is fast, a manufactured sheet may be cracked, or a defect such as a void may occur. Therefore, a temperature condition of each period of the tape casting device may be 30° C. to less than 90° C.

The tape-casted piezoelectric material (or sheet) may be stacked (or laminated), and then, may be pressed for 10 minutes to 30 minutes with pressure of 2,500 psi/cm² to 4,000 psi/cm² at 55° C. to 75° C., but example embodiments of the present disclosure are not limited thereto. For example, the tape-casted piezoelectric material (or sheet) may be stacked, and then, may be compressed for 10 minutes with pressure of 3,000 psi/cm² at 60° C., but example embodiments of the present disclosure are not limited thereto.

A step of performing a primary molding on the tape-casted piezoelectric material may be performed through warm isostatic press (WIP), and a step of performing a secondary molding on the tape-casted piezoelectric material may be performed through cold isostatic press (CIP) and may be used for increasing a density of a sintered material in a sintering step described below. Moreover, in the piezoelectric material composition according to some example embodiments of the present disclosure, the WIP may be performed in a case where a molding element is prepared based on stack and lamination such as tape casting. For example, by the WIP, a stacked piezoelectric material may be maintained and compressed for 10 minutes with pressure of 3,000 psi/cm² or more at 60° C., but example embodiments of the present disclosure are not limited thereto.

The step S130 of molding the piezoelectric material may further include a degreasing step after the primary molding. The degreasing step may be or may include removing a solvent or an organic material. The degreasing step may maintain a molding element in a furnace for 24 hours to 72 hours within a temperature range of 250° C. to 600° C., and then, may cool the molding element up to a room temperature, but example embodiments of the present disclosure are not limited thereto. For example, in the degreasing step, a temperature and a maintenance time of the furnace may be adjusted based on the kinds of dispersant, binder, and plasticizer used therein.

The step S130 of molding the piezoelectric material may include performing a secondary molding after the degreasing step. For example, the secondary molding step may be performed through the CIP. For example, the secondary molding step may be performed at a room temperature and may be maintaining the piezoelectric material for 8 minutes to 12 minutes in 28,000 psi to 30,000 psi, but example embodiments of the present disclosure are not limited thereto. For example, the secondary molding step may be performed at a room temperature and may be maintaining the piezoelectric material for 10 minutes in 29,000 psi, but example embodiments of the present disclosure are not limited thereto.

Subsequently, the step S140 of sintering the molding element to prepare the sintered material (sinter) may be performed in one temperature period, and then, may be cooled. For example, a sintering temperature may be within a range of 950° C. to 1,250° C., but example embodiments of the present disclosure are not limited thereto. For example, when a low-temperature sintering of a molded body, a low-temperature sintering may be performed at 900° C. to 930° C. or 700° C. to 800° C. For example, a sintering maintenance time may be 2 hours to 8 hours, but example embodiments of the present disclosure are not limited thereto.

Subsequently, the step S150 of forming the electrode on the sintered material may form the electrode on a first surface of the sintered material of a piezoelectric material, which is prepared in a previous step, and on a second surface, which is opposite to the first surface, the sintered material of the piezoelectric material. For example, the second surface may differ from the first surface, or may be opposite to the first surface. For example, the electrode may include a metal, for example, may be formed by coating the metal (for example, Ag), but example embodiments of the present disclosure are not limited thereto and the electrode may be used without being limited to a general electrode. For example, the electrode may be formed in the sintered material, a temperature may increase at a temperature increasing rate of 5° C./min, the electrode may be maintained for 10 minutes at 600° C. and then may be naturally cooled at a room temperature, and an electric field of 3 kV/mm may be applied for about 20 minutes at a temperature of 20° C. to 40° C., and thus, a polarization (or poling) process on the electrode may occur, but example embodiments of the present disclosure are not limited thereto.

According to some example embodiments of the present disclosure, a method of manufacturing a piezoelectric material composition may be considerably reduced in time and cost for manufacturing a piezoelectric device, thereby considerably enhancing the productivity of the piezoelectric device.

According to some example embodiments of the present disclosure, productivity may be enhanced, and thus, a desirable manufacturing process may be implemented.

FIG. 3 illustrates a method of manufacturing a matrix material of a piezoelectric material composition according to an example embodiment of the present disclosure. This illustrates a method of manufacturing the matrix material described above with reference to FIG. 2.

Referring to FIG. 3, a method of manufacturing a matrix material of the piezoelectric material composition according to an example embodiment of the present disclosure may include a step S11 of weighing raw materials, a step S12 of mixing the weighed raw materials, a step S13 of calcining and synthesizing the mixed raw materials, and a step S14 of milling a synthesized matrix material. The step S11 of weighing the raw materials may be performed independently of the manufacturing method, or may be omitted. For example, a method of manufacturing a matrix material according to one or more example embodiments of the present disclosure may start from mixing raw materials to form the composition represented by Equation 2. In the following description, a condition (for example, a temperature, pressure, and a time) based on the method of manufacturing the piezoelectric material composition may not limit the details of the present disclosure.

First, the step S11 of weighing the raw material may be or may include weighing a raw material on the basis of a molar ratio to an appropriate amount of solvent.

The matrix material according to some example embodiments of the present disclosure may be expressed as the following Equation 2.

$${aPbZrO}_{3} - {bPbTiO}_{3} - ( 1 - a - b ) Pb ( {Ni}_{c} {Nb}_{1 - c} ) {O}_{3} + x mol \% A \qquad [ Equation 2 ]$$

where A is Fe₂O₃, Co₂O₃, Mn₂O₃, ZnO, GeO₂, CuO, or NiO, and 0.15≤a≤0.24, 0.29≤b≤0.38, 0.30≤c≤0.35, and 0.00≤x≤3.00.

According to some example embodiments of the present disclosure, a matrix material satisfying Equation 2 may be a compound which includes (Pb, Zr, Ti)—(Pb, Ni, Nb) phase and is referred to as PZT-PNN.

A raw material of a matrix material satisfying Equation 2 may include lead oxide (PbO), nickel oxide (NiO), zirconium oxide (ZrO₂), titanium oxide (TiO₂), niobium oxide (Nb₂O₅), and copper oxide (CuO). However, example embodiments of the present disclosure are not limited thereto. For example, the raw material may include oxide including a corresponding positive ion (for example, Pb²⁺, Ni²⁺, Zr⁴⁺, Ti⁴⁺, and Cu²⁺). For example, the step S11 of weighing the raw material may be or may include a process which weighs the raw material on the basis of a molar ratio of a composition to synthesize, adds the weighed raw material to a nylon jar, and adds an appropriate amount of solvent (for example, ethanol), but example embodiments of the present disclosure are not limited thereto. For example, a matrix material including a PZT-PNN composition according to some example embodiments of the present disclosure may be prepared by synthesizing a PZT composition powder and a PNN composition powder, mixing the PZT composition powder and the PNN composition powder, and calcining a mixed composition powder, but example embodiments of the present disclosure are not limited thereto.

The matrix material according to some example embodiments of the present disclosure may include CuO. For example, CuO may be added at 3 mol % or less. For example, CuO may be added at 1.0 mol %. Accordingly, a piezoelectric material according to some example embodiments of the present disclosure may include CuO, and thus, may be capable of low temperature sintering and may increase the sinterability of a piezoelectric material. For example, a low temperature sintering temperature may be 950° C., but example embodiments of the present disclosure are not limited thereto.

Subsequently, the step S12 of mixing the raw materials may be a mixing and a milling the weighed raw materials and a solvent (ethanol) by a ball milling process. For example, the ball milling process may be performed for 12 hours to 36 hours within a range of 100 rpm to 150 rpm, but example embodiments of the present disclosure are not limited thereto.

Some example embodiments of the present disclosure may further include a drying step of separating a powder mixed with the solvent after the step S12 of mixing the raw materials. Here, the drying step may include placing the milled matrix material into a dish and may include drying the milled matrix material at a temperature of 100° C., but example embodiments of the present disclosure are not limited thereto. For example, drying may be performed for 3 hours, but example embodiments of the present disclosure are not limited thereto. Accordingly, the ethanol mixed with the raw material may be removed.

Subsequently, some example embodiments of the present disclosure may include the step S13 of calcining the raw materials. The step S13 of calcining the raw materials may be phase-synthesizing primarily mixed raw materials. The calcining step S13 may include finely grinding a dried compound with a mortar after mixing is completed, placing the grinded compound into an alumina crucible, increasing a temperature of the grinded compound in an electric furnace at a temperature increasing rate of 5° C./min, calcining the compound at 750° C. to 850° C. for 3 hours to 6 hours, and cooling or naturally cooling the calcined compound at a room temperature (or a normal temperature). For example, the calcination temperature may be 700° C. to 900° C. and a maintenance time may be 1 hour to 6 hours, but example embodiments of the present disclosure are not limited thereto. Accordingly, in some example embodiments of the present disclosure, carbonate of the raw material may be removed, and the raw material may uniformly react to form a uniform perovskite phase.

Subsequently, the step S14 of milling the matrix material after calcination ends may be or may include placing the matrix material into Nalgene bottle along with YSZ ball and a solvent (ethanol) and milling the matrix material by a ball milling process to form small particles, but example embodiments of the present disclosure are not limited thereto.

Moreover, the milling step may further include a drying step of separating a powder mixed with the solvent after the milling step S14. Here, the drying step may be or may include placing the milled matrix material into a dish and may include sufficiently drying the milled matrix material at a temperature of 100° C. For example, drying may be performed for 3 hours, but example embodiments of the present disclosure are not limited thereto.

Moreover, according to some example embodiments of the present disclosure, the step S14 of milling the phase-synthesized matrix material may further include sieving a material.

The sieving step may be or may include filtering out dried powders finely grinded by the mortar by a 40-mesh sieve to produce powders including particles having a certain size or less. A powder passing through the 40-mesh sieve may have a size of 400 μm or less, but example embodiments of the present disclosure are not limited thereto.

FIG. 4 illustrates a method of manufacturing a seed material of a piezoelectric material composition according to an example embodiment of the present disclosure. This illustrates a method of manufacturing a seed material in the method of manufacturing the piezoelectric material composition described above with reference to FIG. 2.

Referring to FIG. 4, a method of manufacturing a seed material of a piezoelectric material composition according to an example embodiment of the present disclosure may include a step S21 of primarily weighing a seed material, a step S22 of preparing a primary seed, a step S23 of performing secondary weighing, a step S24 of preparing a secondary seed, a step S25 of performing tertiary weighing, and a step S26 of preparing a tertiary seed. For example, a step of preparing the primary seed and the secondary seed may be prepared by a molten salt method, and the step S26 of preparing the tertiary seed may be prepared by a topochemical method. For example, the molten salt method may be a process for manufacturing a powder of a certain nano-structure type and may be a method which mixes a matrix composition with a raw material and a salt-based powder having a low melting point to allow annealing at a high temperature. The salt-based powder may become molten at a high temperature to function as a solvent, and a raw material may react in the molten salt-based powder (solvent) to form a powder having a nano-structure. For example, a melted raw material and the solvent may be cooled in a molten state, and salt may be removed by water after cooling. Accordingly, a powder having a nano-structure where morphology is not damaged may be obtained.

First, the step S21 of primarily weighing the seed material may be or may include a step of weighing a primary seed material, based on a molar ratio. Here, a composition which is to be synthesized may be Bi₄Ti₃O₁₂.

For example, the step S21 of primarily weighing the seed material may be a step of weighing Bi₂O₃, TiO₂, NaCl, and KCl, based on a molar ratio of a composition to be synthesized, and placing the weighed material into a nylon jar. For example, in the primary weighing step S21, a ratio of NaCl to KCl may be 1:1, but example embodiments of the present disclosure are not limited thereto.

Subsequently, the step S22 of preparing the primary seed may include a step of mixing weighed materials and a step of phase-synthesizing mixed materials.

For example, the mixing step may be a step of mixing and milling the primary seed material for 12 hours by a ball mill process. Also, the step S22 of preparing the primary seed may further include a step of performing drying for removing water after mixing and milling are completed. Here, the drying step may be or may include placing the primarily mixed seed material into a dish and may include drying the mixed seed material at a temperature of 100° C. to 120° C., but example embodiments of the present disclosure are not limited thereto.

For example, the phase-synthesizing step may be or may include mixing and drying the primary seed materials, calcining a dried primary seed material for 6 hours at 1,100° C., and cooling or naturally cooling a calcined primary seed material at a room temperature (or a normal temperature), but example embodiments of the present disclosure are not limited thereto. For example, the cooled primary seed material may be cleaned by de-ionized water (DI-water). At this time, salt included in a raw material may be cleaned. Accordingly, Bi₄Ti₃O₁₂ having a plate shape may be manufactured as in the following Chemical Formula 1.

Bi₂O₃+3TiO₂→Bi₄Ti₃O₁₂ [Chemical Formula 1]

Subsequently, the step S23 of performing secondary weighing of the seed material may be a step of weighing the secondary seed material, based on a molar ratio. Here, a molar ratio of a composition to be synthesized in the secondary seed may be BaBi₄Ti₄O₁₅.

For example, the step S23 of performing secondary weighing of the seed material may be or may include weighing a primary material (for example, Bi₄Ti₃O₁₂, BaCO₃, TiO₂, BaCl₂, or KCl), based on a molar ratio of a composition which is to be synthesized, and placing a weighed primary material into a nylon jar.

Subsequently, the step of preparing the secondary seed may include mixing the materials which have been weighed in the previous step and phase-synthesizing a mixed material.

For example, the weighed material may be mixed with a solvent and may be mixed through stirring using a magnetic bar. Also, the step S24 of preparing the secondary seed may further include performing drying after mixing is completed. Here, the drying step may be or may include placing a primarily-mixed secondary seed material into a dish and performing drying at a temperature of 100° C. to 120° C., but example embodiments of the present disclosure are not limited thereto. For example, drying may be performed for 3 hours while stirring, but example embodiments of the present disclosure are not limited thereto.

For example, the step of phase-synthesizing the mixed material may be or may include mixing and drying the primary seed materials, calcining a dried secondary seed material for 1 hour at 1,080° C., and cooling or naturally cooling a calcined primary seed material at a room temperature (or a normal temperature), but example embodiments of the present disclosure are not limited thereto. For example, the secondary seed material may be cleaned by using DI-water. At this time, salt included in a raw material may be cleaned. Accordingly, BaBi₄Ti₄O₁₅ having a plate shape may be manufactured as in the following Chemical Formula 2.

Bi₄Ti₃O₁₂+BaCO₃+4TiO₂→BaBi₄Ti₄O₁₅+CO₂ [Chemical Formula 2]

Subsequently, a tertiary weighing step S25 may be or may include placing a material including sodium (Na) for substituting the secondary seed powder and bismuth (Bi) of the secondary seed powder and weighing the material, based on a molar ratio of a composition. Here, a composition of the tertiary seed may be BaTiO₃. Hereinafter, therefore, the tertiary seed may be referred to as a “BT seed”.

For example, the tertiary weighting step S25 may be or may include weighing a secondary material (for example, BaBi₄Ti₄O₁₅, BaCO₃, NaCl, and KCl), based on a molar ratio of a composition which is to be synthesized, and placing a weighed secondary material into a nylon jar.

Subsequently, the step S26 of preparing the tertiary seed may include a step of mixing tertiary weighed materials and a step of performing a topochemical reaction.

For example, the mixing step may be a process that includes adding ethanol to the tertiary weighed material, placing a magnetic bar into a beaker, and performing stirring for 6 hours with 80 rpm, but example embodiments of the present disclosure are not limited thereto.

Moreover, the step of preparing the tertiary seed may further include a step of drying a mixed secondary weighed material. Here, the drying step may be or may include placing a compound (or a mixture) into a dish and may include drying the compound for 3 hours to 6 hours at a temperature of 80° C. to 100° C., but example embodiments of the present disclosure are not limited thereto.

Moreover, a temperature may increase up to 950° C. from a room temperature at a temperature increasing rate of 10° C./min and then may be maintained for 3 hours, and then a mixed powder, which may be dried completed, may be naturally cooled, but example embodiments of the present disclosure are not limited thereto.

For example, the step of performing the topochemical reaction may include placing a dried tertiary seed material into a crucible and may be performed for 3 hours at 950° C., but example embodiments of the present disclosure are not limited thereto. By performing the topochemical reaction, Bi included in the secondary seed may be replaced with Na. Here, the step of performing the topochemical reaction may be referred to as tertiary calcination. The step S26 of preparing the tertiary seed may further include a step of cleaning a tertiary seed on which the topochemical reaction is completed.

For example, the step of cleaning the tertiary seed may clean and filter the tertiary seed two to ten times by distilled water of 80° C. or more so as to remove sodium chloride (NaCl) stained on a BT seed, but example embodiments of the present disclosure are not limited thereto. Remnant ions Na⁺ and Cl⁻ may be removed by filtering, and drying may be performed for 3 hours to 6 hours in an oven of 90° C. to 100° C. after the filtering. Accordingly, BaTiO₃ may be manufactured as in the following Chemical Formula 3. BaTiO₃ may have a plate shape.

BaBi₄Ti₄O₁₅+BaCO₃→2BaTiO₃+2Bi₂O₃+CO₂ [Chemical Formula 3]

Additionally, in the method of preparing a seed material according to some example embodiments of the present disclosure, even after the cleaning and the filtering, acid treatment may be performed with nitric acid several times so as to remove Bi³⁺ ions and Bi₂O₃ remaining in the BT seed, and then, neutralization cleaning may be performed with water after the acid treatment. For example, nitric acid may be added to a beaker, the BT seed may be added, and shaking may be performed at every 10 minutes. This may be repeatedly performed for 10 minutes to 2 hours, but example embodiments of the present disclosure are not limited thereto. For example, bismuth remnant materials may be ionized by performing acid treatment for 20 minutes two to three times by nitric acid, and then, may be filtered. For example, a ratio of sodium chloride (NaCl) to potassium chloride (KCl) may be 1:4 (mol), but example embodiments of the present disclosure are not limited thereto.

Moreover, in order to remove some remnant nitric acid neutralization and Bi³⁺ ions, cleaning may be performed once to twice by distilled water, and then, remnant ions Bi³⁺ may be removed by filtering. Drying may be performed for 3 hours to 6 hours in an oven of 90° C. to 100° C. after filtering.

Accordingly, BaTiO₃ having a plate shape according to some example embodiments of the present disclosure may be prepared.

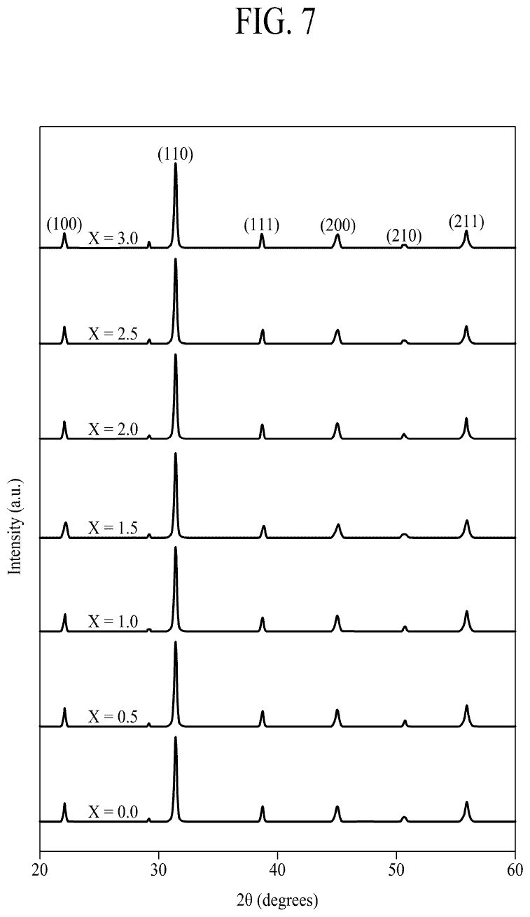

FIG. 5 illustrates a grain variation occurring in the step of preparing the tertiary seed according to the example embodiment illustrated in FIG. 4. In FIG. 5, a crystal structure having a composition of Bi₂O₂(Bi₂Ti₃O₁₀) illustrated on a left side of FIG. 5 shows a primary seed (Bi₄Ti₃O₁₂), and a crystal structure having a composition of Bi₂O₂(BaBi₂Ti₄O₁₃) illustrated in a center region of FIG. 5 shows a secondary seed (BaBi₄Ti₄O₁₅). In FIG. 5, a crystal structure having a composition of BaTiO₃ illustrated in a right side of FIG. 5 shows a tertiary seed and may be referred to as a BT seed.

Referring to FIG. 5, a crystal structure of the primary seed having a composition of Bi₂O₂(Bi₂Ti₃O₁₀) may be a structure where a layer in which Bi is provided between TiO₆ octahedrons is configured between Bi₂O₂. Also, a crystal structure of the secondary seed having a composition of Bi₂O₂(BaBi₂Ti₄O₁₃) may be a structure where a layer in which barium (Ba) and bismuth (Bi) are provided between TiO₆ octahedrons is configured between Bi₂O₂. Also, a crystal structure of the tertiary seed having a composition of BaTiO₃ may be a structure where barium (Ba) is surrounded with TiO₃ octahedron therebetween.

For example, the secondary seed may be changed to the tertiary seed by a topochemical reaction in the step of preparing the tertiary seed. Here, the topochemical reaction may denote a chemical reaction where a direction of orientation of a mother grain and a grain direction of orientation of a product has different relationships in direction of orientation but a shape of a crystal particle is maintained, in a solid-phase chemical reaction.

Therefore, as shown in FIG. 5, in a process of substituting a titanium (Ti) element of the secondary seed into a barium (Ba) element, a structure where a layer where Ba and Bi are provided between TiO₆ octahedrons is configured between Bi₂O₂ may be changed to a single structure having a composition of BaTiO₃.

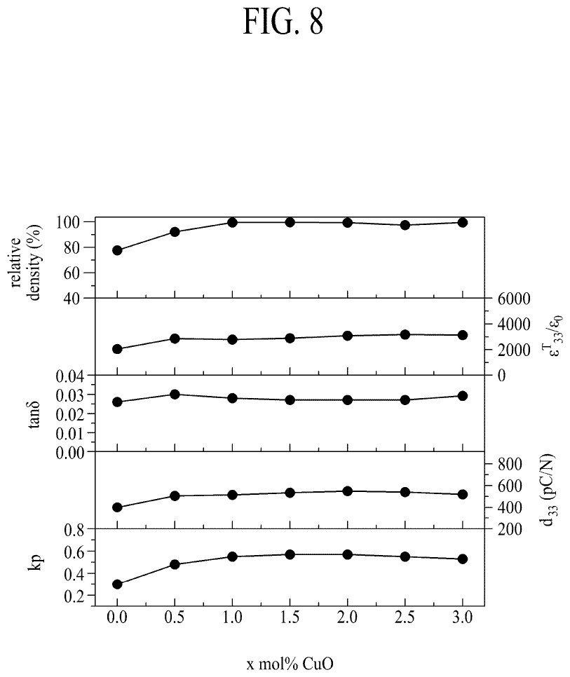

FIGS. 6A to 6C are each a scanning electron microscope (SEM) image and show the grain variation occurring in the step of preparing the tertiary seed according to the example embodiment illustrated in FIG. 5. FIG. 6A shows a primary seed, FIG. 6B shows a secondary seed, and FIG. 6C shows a tertiary seed.

Referring to FIGS. 6A to 6C, it may be seen that a BaTiO₃ seed having a plate structure may be easily manufactured through a step of preparing the primary seed, the secondary seed, and the tertiary seed.

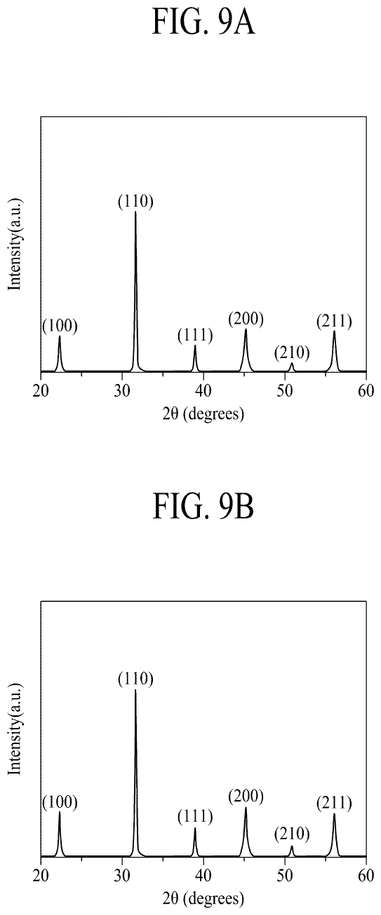

FIG. 7 is a graph showing X-ray diffraction patterns with respect to a CuO content of a piezoelectric material composition according to an example embodiment of the present disclosure. In FIG. 7, the X-axis represents a 20 (degrees) value of X-ray diffraction, and the ordinate axis represents a relative intensity.

The inventors have measured an X-ray diffraction pattern with respect to a variation of x in Equation 2 which is the matrix material of the piezoelectric material composition described above with reference to FIG. 1, so as to analyze an X-ray diffraction pattern based on a copper oxide (CuO) content. For example, the matrix material of the piezoelectric material composition described above with reference to FIG. 1 may be a matrix material where a seed may be excluded and may be expressed as a non-TGG piezoelectric material composition. Non-TGG may be that a grain growth process is randomly performed without a seed. A composition of the non-TGG piezoelectric material composition may be aPbZrO₃-bPbTiO₃-(1-a-b)Pb(Ni_{c}Nb_{1-c})O₃+x mol % CuO. For example, the piezoelectric material composition according to some example embodiments of the present disclosure has been configured with 0.15≤a≤0.24, 0.29≤b≤0.38, 0.30≤c≤0.35. For example, in the piezoelectric material composition according to some example embodiments of the present disclosure, values of x (or CuO contents) have been prepared as 0.0, 0.5, 1.0, 1.5, 2.0, 2.5, and 3.0. For example, in the piezoelectric material composition according to some example embodiments of the present disclosure, a sintering temperature of each sample has been prepared as 950° C., and a sintering time has been prepared as 10 hours.

Referring to FIG. 7, in the non-TGG piezoelectric material composition according to an example embodiment of the present disclosure, when CuO contents (or values of x in Equation 1) are 0.0, 0.5, 1.0, 1.5, 2.0, 2.5, and 3.0, it may be confirmed that grain growth is performed in a (100) orientation and a (110) orientation.

Moreover, when CuO contents (or values of x in Equation 2) are 0.0, 0.5, 1.0, 1.5, 2.0, 2.5, and 3.0, it may be confirmed that a piezoelectric material composition has a pure perovskite structure, there is no change in a crystal structure caused by addition of CuO, and a very small amount of secondary phase is observed. Accordingly, in some example embodiments of the present disclosure, it may be confirmed that the piezoelectric material composition is smoothly sintered at a low temperature of 950° C.

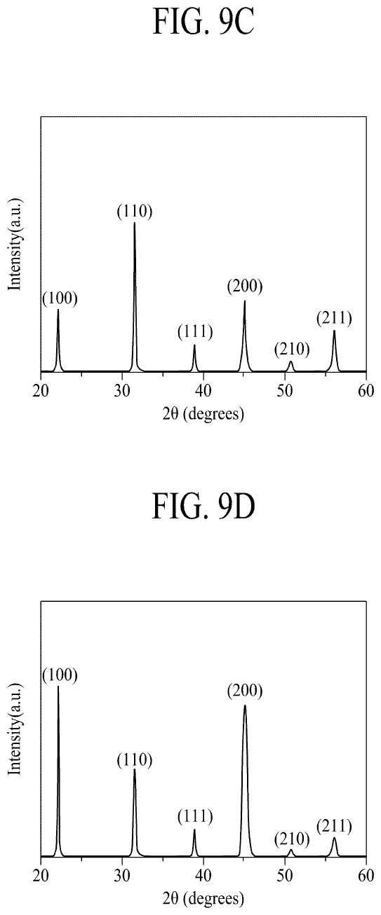

FIG. 8 is a graph showing a relative density (%), a dielectric constant ε^{T}₃₃/ε₀, a loss factor tan δ, a piezoelectric charge constant d₃₃, and an electromechanical coupling factor k_{ρ} with respect to a copper oxide (CuO) content of a piezoelectric material composition according to an example embodiment of the present disclosure. In FIG. 8, a composition of each sample based on a change in CuO content of a composition has been prepared by the same method as the sample of the non-TGG composition of FIG. 5, and values of x have been set to 0.0, 0.5, 1.0, 1.5, 2.0, 2.5, and 3.0, respectively.

Referring to FIG. 8, a relative density (%) according to an example embodiment of the present disclosure has been measured to be 77.6% and 92.2% in samples where CuO contents are 0.0 and 0.5, respectively. The relative density (%) according to some example embodiments of the present disclosure represents values of 99.4% to 99.7% in all samples where CuO contents are 1.0, 1.5, 2.0, 2.5, and 3.0, respectively. Accordingly, it has been confirmed that sintering is smoothly performed at a low temperature as CuO is added, and when CuO of 1.0 mol % to 3.0 mol % is added, it has been confirmed that sintering is performed close to 100% relative density. As used herein, the term “relative density” may be calculated by dividing the density of the actual sample by the density of an ideal sample with no defects.

A dielectric constant ε^{T}₃₃/ε₀ has been measured to be 2069 in a sample, where a CuO content is 0.0, and represents values of 2867 to 3169 in samples where CuO contents are 0.5, 1.0, 1.5, 2.0, 2.5, and 3.0, respectively. When CuO contents are 0.5, 1.0, 1.5, 2.0, 2.5, and 3.0, dielectric constants have been measured to be 2867, 2792, 2887, 3088, 3169, and 3140. Accordingly, in some example embodiments of the present disclosure, it has been confirmed that a dielectric constant increases more in a case, where CuO is added, than a case where CuO is not added.

A loss factor tan δ has values of 0.02 to 0.05 in samples where CuO contents are 0.0, 0.5, 1.0, 1.5, 2.0, 2.5, and 3.0, respectively. In the loss factor tan δ, comparing with a case where CuO is not added, in a case where CuO is added, a dielectric constant has slightly increased, but a dielectric constant difference has not been large. Also, the loss factor tan δ represents a similar value in a case where CuO contents are between 1.0 and 2.5. Accordingly, it has been confirmed that a CuO content does not largely affect the loss factor tan δ.

A piezoelectric charge constant d₃₃ represents values of 400 pC/N to 550 pC/N in samples where CuO contents are 0.0, 0.5, 1.0, 1.5, 2.0, 2.5, and 3.0. The piezoelectric charge constant d₃₃ represents values of 400 pC/N, 505 pC/N, 515 pC/N, 535 pC/N, 550 pC/N, 540 pC/N, and 520 pC/N in samples where CuO contents are 0.0, 0.5, 1.0, 1.5, 2.0, 2.5, and 3.0. The piezoelectric charge constant d₃₃ has increased more in a case, where a CuO content is 0.5, than a case where a CuO content is 0.0. In the piezoelectric charge constant d₃₃, a CuO content has increased to 0.5 to 2.0, but the piezoelectric charge constant d₃₃ has again decreased as a CuO content increases to 2.5 and 3.0. Accordingly, in some example embodiments of the present disclosure, the piezoelectric charge constant d₃₃ has been highest when a CuO content is 2.0, and thus, it has been confirmed that a piezoelectric characteristic is good.

An electromechanical coupling factor kρ represents values of 0.30 to 0.53 in samples where CuO contents are 0.0, 0.5, 1.0, 1.5, 2.0, 2.5, and 3.0, respectively. The electromechanical coupling factor kρ represents values of 0.30, 0.48, 0.55, 0.57, 0.57, 0.55, and 0.53 in samples where CuO contents are 0.0, 0.5, 1.0, 1.5, 2.0, 2.5, and 3.0, respectively. The electromechanical coupling factor kρ has increased about 0.18 more in a case, where a CuO content is 0.5, than a case where a CuO content is 0.0. It has been confirmed that the electromechanical coupling factor kρ has values of 0.53 to 0.57 in a case where a CuO content is between 1.0 and 3.0. It has been confirmed that the electromechanical coupling factor kρ has a highest value of 0.57 in a case where CuO contents are 1.5 and 2.0.

The inventors have calculated a desirable CuO content by analyzing a relative density (%), a loss factor tan δ, a piezoelectric charge constant d₃₃, and an electromechanical coupling factor k_{ρ}. For example, according to some example embodiments of the present disclosure, it has been confirmed that a piezoelectric material has a best piezoelectric characteristic in a case where a desirable CuO content is 1.0 to 2.0.

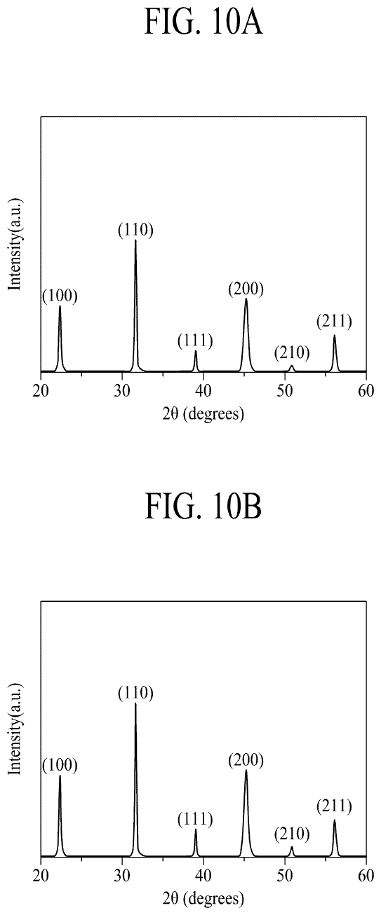

FIGS. 9A to 9D each illustrates an X-ray diffractometer (XRD) pattern of a seed content of a piezoelectric material composition according to an example embodiment of the present disclosure.

The inventors have measured an X-ray diffraction pattern with respect to a variation of y in Equation 1 of the piezoelectric material composition described above with reference to FIG. 1, so as to analyze an X-ray diffraction pattern based on a seed content. For example, the piezoelectric material composition described above with reference to FIG. 1 may include a seed and may be expressed as a TGG piezoelectric material composition. A composition of the TGG piezoelectric material composition may be aPbZrO₃-bPbTiO₃-(1-a-b)Pb(Ni_{c}Nb_{1-c})O₃+x mol % CuO+y vol % BaTiO₃. For example, the piezoelectric material composition according to some example embodiments of the present disclosure has been configured with 0.15≤a≤0.24, 0.29≤b≤0.38, 0.30≤c≤0.35, 0.00≤x≤3.00. For example, in FIGS. 9A to 9D, a value of y (or a content of BaTiO₃) have been set to 1. For example, for FIGS. 9A to 9D, a sample has been prepared where sintering temperatures are 950° C., 1,050° C., 1150° C., and 1,250° C., respectively, and a sintering time is 10 hours. Such an experiment condition does not limit the details of the present disclosure.

Referring to FIGS. 9A to 9D, it has been confirmed that a piezoelectric material composition is synthesized in a perovskite structure and a secondary phase and an unreacted phase are not observed in all samples.

The following Table 1 may be a table which shows a Lotgering factor of a sample where sintering temperatures described with reference to FIGS. 9A to 9D are 950° C., 1,050° C., 1,150° C., and 1,250° C., respectively.

TABLE 1

| (vol %) of BaTiO₃ | Sintering Temperature | Lotgering Factor (%) |
|---|---|---|
| 1 | 950° C. | 12.7 |
| 1 | 1,050° C. | 14.2 |
| 1 | 1,150° C. | 27.5 |
| 1 | 1,250° C. | 70.0 |

Referring to Table 1, the Lotgering factor based on the sintering temperature of the piezoelectric material composition according to some example embodiments of the present disclosure increases as the sintering temperature increases. For example, the Lotgering factor represents the degree of orientation of a sample, and when the Lotgering factor is 100%, it may be considered that orientation is completely performed. For example, the Lotgering factor L_{f(%)} may be expressed as the following Mathematical formula 1.

$${L}_{f} ( \% ) = \frac{p - {p}_{0}}{1 - {p}_{0}} \qquad [ Mathematical formula 1 ]$$

In Mathematical formula 1, p may denote the degree of orientation calculated by Mathematical formula 1, and p₀ may denote a fraction of I₀₀₁ in a piezoelectric material composition which is randomly oriented or has substantially the same composition. The degree of orientation p may be calculated as the following Mathematical formula 2.

$$p = \frac{\sum {I}_{001}}{\sum {I}_{001} + \sum {I}_{non - 001}} \qquad [ Mathematical formula 2 ]$$

In Mathematical formula 2, I₍₀₀₁₎ may denote a diffraction peak such as (001) and (002) expressed as (001), and Iₙₒₙ₋₍₀₀₁₎ may denote a diffraction peak such as (110), (111), (210), and (211), which are not expressed as (001).

According to some example embodiments of the present disclosure, Lotgering factors of samples where a content of BaTiO₃ is 1 vol % of an entire piezoelectric material composition and sintering temperatures are 950° C., 1,050° C., 1,150° C., and 1,250° C. have been measured to be 12.7%, 14.2%, 27.5%, and 70.0%, respectively.

According to some example embodiments of the present disclosure, it has been confirmed that a Lotgering factor increases as sintering temperatures increase to 950° C., 1,050° C., 1,150° C., and 1,250° C., under a condition where a content of BaTiO₃ is 1 vol %. Accordingly, the inventors have confirmed that the degree of orientation of a sample is best when a sintering temperature is 1,250° C., under a condition where a content of BaTiO₃ is 1 vol % of the entire piezoelectric material composition.

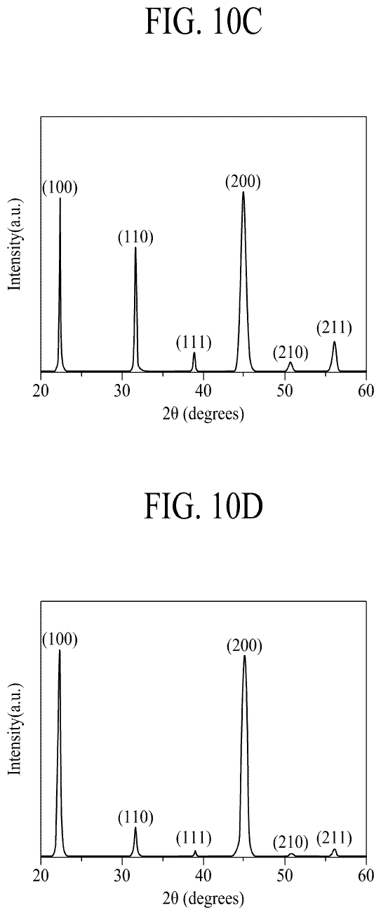

FIGS. 10A to 10D each illustrates an XRD pattern of a seed content of a piezoelectric material composition according to another example embodiment of the present disclosure.

FIGS. 10A to 10D are for analyzing an X-ray diffraction pattern with respect to a seed content, and a sample has been prepared in a similar manner as the samples for FIGS. 9A to 9D. However, in FIGS. 10A to 10D, a value of y (or a content of BaTiO₃) is set to 3. Hereinafter, therefore, only different elements will be described.

Referring to FIGS. 10A to 10D, it has been confirmed that a piezoelectric material composition is synthesized in a perovskite structure and a secondary phase and an unreacted phase are not observed in all samples.

The following Table 2 may be a table which shows a Lotgering factor of a sample where sintering temperatures described with reference to FIGS. 10A to 10D are 950° C., 1,050° C., 1,150° C., and 1,250° C., respectively.

TABLE 2

| (vol %) of BaTiO₃ | Sintering Temperature | Lotgering Factor (%) |
|---|---|---|
| 3 | 950° C. | 36.6 |
| 3 | 1,050° C. | 39.4 |
| 3 | 1,150° C. | 63.5 |
| 3 | 1,250° C. | 88.7 |

Referring to Table 2, the Lotgering factor based on the sintering temperature of the piezoelectric material composition according to some example embodiments of the present disclosure increases as the sintering temperature increases.

According to some example embodiments of the present disclosure, Lotgering factors of samples where a content of BaTiO₃ is 3 vol % of an entire piezoelectric material composition and sintering temperatures are 950° C., 1,050° C., 1,150° C., and 1,250° C. have been measured to be 36.6%, 39.4%, 63.5%, and 88.7%, respectively.

According to some example embodiments of the present disclosure, it has been confirmed that a Lotgering factor increases as sintering temperatures increase to 950° C., 1,050° C., 1,150° C., and 1,250° C., under a condition where a content of BaTiO₃ is 3 vol %. Accordingly, the inventors have confirmed that the degree of orientation of a sample is best when a sintering temperature is 1,250° C., under a condition where a content of BaTiO₃ is 3 vol % of the entire piezoelectric material composition.

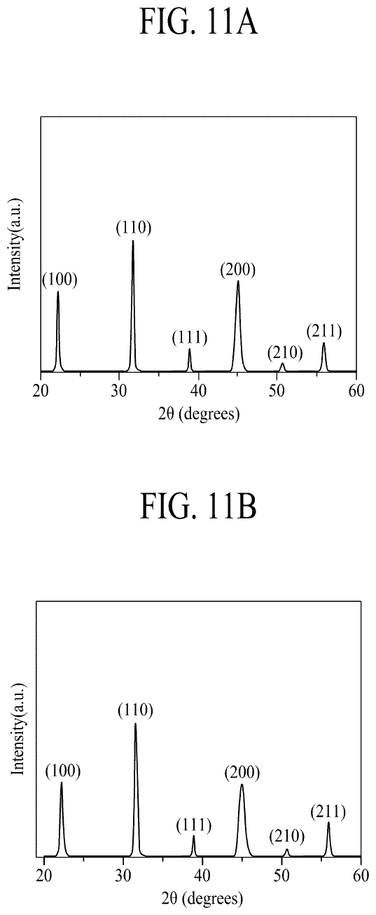

FIGS. 11A to 11D each illustrates an XRD pattern of a seed content of a piezoelectric material composition according to another example embodiment of the present disclosure.

FIGS. 11A to 11D are for analyzing an X-ray diffraction pattern with respect to a seed content, and a sample has been prepared in a similar manner as the samples for FIGS. 9A to 9D. However, in FIGS. 11A to 11D, a value of y (or a content of BaTiO₃) is set to 5. Hereinafter, therefore, only different elements will be described.

Referring to FIGS. 11A to 11D, it has been confirmed that a piezoelectric material composition is synthesized in a perovskite structure and a secondary phase and an unreacted phase are not observed in all samples.

The following Table 3 may be a table which shows a Lotgering factor of a sample where sintering temperatures described with reference to FIGS. 11A to 11D are 950° C., 1,050° C., 1,150° C., and 1,250° C., respectively.

TABLE 3

| (vol %) of BaTiO₃ | Sintering Temperature | Lotgering Factor (%) |
|---|---|---|
| 5 | 950° C. | 44.0 |
| 5 | 1,050° C. | 38.0 |
| 5 | 1,150° C. | 66.5 |
| 5 | 1,250° C. | 91.0 |

Referring to Table 3, the Lotgering factor based on the sintering temperature of the piezoelectric material composition according to some example embodiments of the present disclosure slightly decreases as the sintering temperature increases from 950° C. to 1,050° C., but increases again as the sintering temperature increases to 1,150° C. and 1,250° C.

According to some example embodiments of the present disclosure, Lotgering factors of samples where a content of BaTiO₃ is 5 vol % of an entire piezoelectric material composition and sintering temperatures are 950° C., 1,050° C., 1,150° C., and 1,250° C. have been measured to be 44.0%, 38.0%, 66.5%, and 91.0%, respectively.

According to some example embodiments of the present disclosure, it has been confirmed that a Lotgering factor slightly decreases as sintering temperatures increase to 950° C., 1,050° C., 1,150° C., and 1,250° C., under a condition where a content of BaTiO₃ is 5 vol %. Accordingly, the inventors have confirmed that the degree of orientation of a sample is best when a sintering temperature is 1,250° C., under a condition where a content of BaTiO₃ is 5 vol % of the entire piezoelectric material composition.

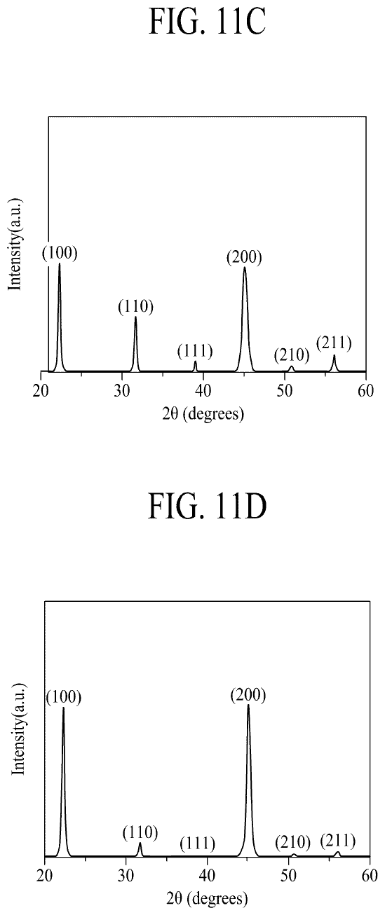

FIGS. 12A to 12D each illustrates an XRD pattern of a seed content of a piezoelectric material composition according to another example embodiment of the present disclosure.

FIGS. 12A to 12D are for analyzing an X-ray diffraction pattern with respect to a seed content, and a sample has been prepared in a similar manner as the samples for FIGS. 9A to 9D. However, in FIGS. 12A to 12D, a value of y (or a content of BaTiO₃) is set to 7. Hereinafter, therefore, only different elements will be described.

Referring to FIGS. 12A to 12D, it has been confirmed that a piezoelectric material composition is synthesized in a perovskite structure and a secondary phase and an unreacted phase are not observed in all samples.

The following Table 4 may be a table which shows a Lotgering factor of a sample where sintering temperatures described with reference to FIGS. 12A to 12D are 950° C., 1,050° C., 1,150° C., and 1,250° C., respectively.

TABLE 4

| (vol %) of BaTiO₃ | Sintering Temperature | Lotgering Factor (%) |
|---|---|---|
| 7 | 950° C. | 53.2 |
| 7 | 1,050° C. | 49.2 |
| 7 | 1,150° C. | 79.3 |
| 7 | 1,250° C. | 91.5 |

Referring to Table 4, the Lotgering factor based on the sintering temperature of the piezoelectric material composition according to some example embodiments of the present disclosure slightly decreases as the sintering temperature increases from 950° C. to 1,050° C., but increases again as the sintering temperature increases to 1,150° C. and 1,250° C.

According to some example embodiments of the present disclosure, Lotgering factors of samples where a content of BaTiO₃ is 7 vol % of an entire piezoelectric material composition and sintering temperatures are 950° C., 1,050° C., 1,150° C., and 1,250° C. have been measured to be 53.2%, 49.2%, 79.3%, and 91.5%, respectively.

According to some example embodiments of the present disclosure, it has been confirmed that a Lotgering factor slightly decreases as sintering temperatures increase to 950° C., 1,050° C., 1,150° C., and 1,250° C., under a condition where a content of BaTiO₃ is 7 vol %. Accordingly, the inventors have confirmed that the degree of orientation of a sample is best when a sintering temperature is 1,250° C., under a condition where a content of BaTiO₃ is 7 vol % of the entire piezoelectric material composition.

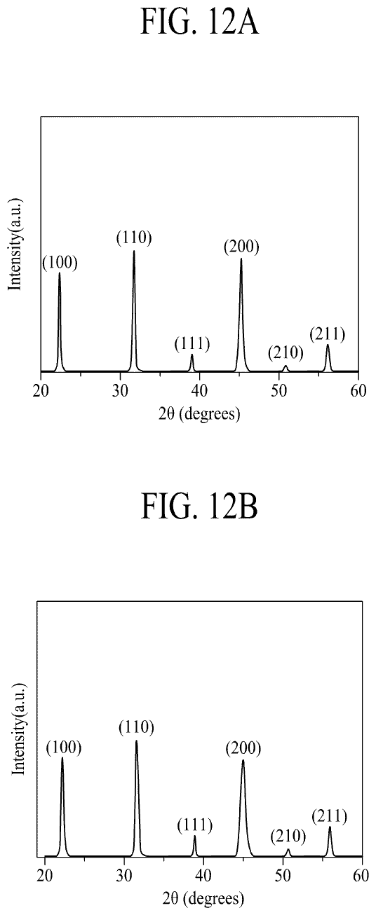

FIG. 13 illustrates a Lotgering factor with respect to a BaTiO₃ content and a sintering temperature of a piezoelectric material composition according to an example embodiment of the present disclosure.

FIG. 13 is for analyzing a Lotgering factor with respect to a BaTiO₃ content and a sintering temperature of a piezoelectric material composition, a sample has been prepared in a similar manner as the samples for FIGS. 9A to 9D, and a value of y (or a content of BaTiO₃) is set to 1 vol %, 3 vol %, 5 vol %, and 7 vol % of an entire piezoelectric material composition. In FIG. 13, a dotted line represents that a value of y (or a content of BaTiO₃) is 1 vol %, a dash-single dotted line represents that a value of y (or a content of BaTiO₃) is 3 vol %, a dash-two dotted line represents that a value of y (or a content of BaTiO₃) is 5 vol %, and a thin solid line represents that a value of y (or a content of BaTiO₃) is 7 vol %.

Referring to FIG. 13, the Lotgering factor based on the sintering temperature of the piezoelectric material composition according to an example embodiment of the present disclosure increases as the sintering temperature increases. When the sintering temperature is 1,250° C., it has been confirmed that the Lotgering factor of 70% or more is shown in all samples. Also, according to some example embodiments of the present disclosure, it has been confirmed that the Lotgering factor increases as a value of y (or a content of BaTiO₃) increases.

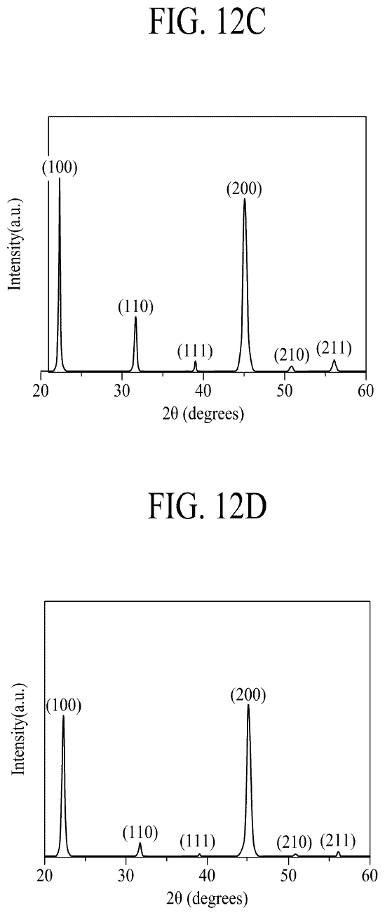

FIG. 14 is a graph showing a relative density (%), a piezoelectric charge constant d₃₃ (pC/N), an electromechanical coupling factor k_{ρ}, a dielectric constant ε^{T}₃₃/ε₀, and a loss factor tan δ with respect to a sintering temperature of a piezoelectric material composition according to an example embodiment of the present disclosure.

FIG. 14 is for analyzing a relative density (%), a dielectric constant ε^{T}₃₃/ε₀, a loss factor tan δ, a piezoelectric charge constant d₃₃, and an electromechanical coupling factor k_{ρ} with respect to a BaTiO₃ content and a sintering temperature of a piezoelectric material composition, and a sample has been prepared in a similar manner as the samples for FIGS. 9A to 9D. A sintering temperature is set to 950° C., 1,000° C., 1,050° C., 1,100° C., 1,150° C., 1,200° C., and 1,250° C., and a value of y (or a content of BaTiO₃) is set to 1 vol %, 3 vol %, 5 vol %, and 7 vol % of an entire piezoelectric material composition. In FIG. 14, the abscissa axis represents a sintering temperature, a dotted line represents that a value of y (or a content of BaTiO₃) is 1 vol %, a dash-single dotted line represents that a value of y (or a content of BaTiO₃) is 3 vol %, a dash-two dotted line represents that a value of y (or a content of BaTiO₃) is 5 vol %, and a thin solid line represents that a value of y (or a content of BaTiO₃) is 7 vol %.

Referring to FIG. 14, a relative density (%) based on a sintering temperature of a piezoelectric material composition according to an example embodiment of the present disclosure represents a value of 90% or more in all samples. A relative density in all samples represents a value of 95% or more with respect to 950° C. to 1,150° C. and represents a value of 90% to less than 95% with respect to 1,150° C. to 1,250° C. Therefore, in some example embodiments of the present disclosure, it has been confirmed that, as BaTiO₃ is added, sintering where a relative density is 95% or more is performed at a low temperature of 950° C. to 1,150° C. Accordingly, in the piezoelectric material composition according to some example embodiments of the present disclosure, it has been confirmed that, as BaTiO₃ is added, sintering is smoothly performed at a low temperature of 950° C. to 1,150° C.

A dielectric constant ε^{T}₃₃/ε₀ based on a sintering temperature of the piezoelectric material composition according to some example embodiments of the present disclosure has a value of 2,700 to 4,000 in all samples. Dielectric constants of all samples have similar values between 2,800 to 3,000 with respect to a sintering temperature of 950° C. to 1,200° C. A sample where the amount of addition of BaTiO₃ of the piezoelectric material composition is 1 vol % of an entire piezoelectric material composition has a value of about 3,500 with respect to a sintering temperature of 1,250° C., but decreases again with respect to a temperature of more than 1,250° C.

In all samples, it has been confirmed that a loss factor tan δ based on the sintering temperature of the piezoelectric material composition according to some example embodiments of the present disclosure increases as the sintering temperature increases, and then, the loss factor decreases. The loss factor has a value between 0.01 to 0.04.

In the piezoelectric material composition according to some example embodiments of the present disclosure, the piezoelectric charge constant d₃₃ based on the sintering temperature of the piezoelectric material composition increases as the sintering temperature increases, and then, decreases with respect to a temperature of 1,250° C. In a sample where a content of BaTiO₃ is 1 vol % and 3 vol % of the entire piezoelectric material composition, as the sintering temperature increases to 950° C. to 1,250° C., a piezoelectric constant increases up to 790 pC/N from 405 pC/N, and the piezoelectric constant decreases with respect to a temperature of more than 1,250° C. In a sample where a content of BaTiO₃ is 5 vol % and 7 vol % of the entire piezoelectric material composition, as the sintering temperature increases to 950° C. to 1,200° C., the piezoelectric constant increases, and a piezoelectric constant value decreases with respect to a temperature of 1,250° C. or more. A piezoelectric constant of each sample has been measured to be a value of 400 pC/N to 790 pC/N with respect to a sintering temperature of 950° C. to 1,250° C. Accordingly, in the piezoelectric material composition according to some example embodiments of the present disclosure, it has been confirmed that a piezoelectric characteristic is enhanced as a BaTiO₃ seed is added.

The electromechanical coupling factor kρ based on the sintering temperature of the piezoelectric material composition according to some example embodiments of the present disclosure has a value between 0.41 and 0.62.

In the piezoelectric material composition according to some example embodiments of the present disclosure, a relative density (%), a dielectric constant ε^{T}₃₃/ε₀, a loss factor tan δ, a piezoelectric charge constant d₃₃, and an electromechanical coupling factor k_{ρ} based on a content of BaTiO₃ of the piezoelectric material composition have similar characteristics in all samples where values of y (or a content of BaTiO₃) are 1 vol %, 3 vol %, 5 vol %, and 7 vol % of the entire piezoelectric material composition.

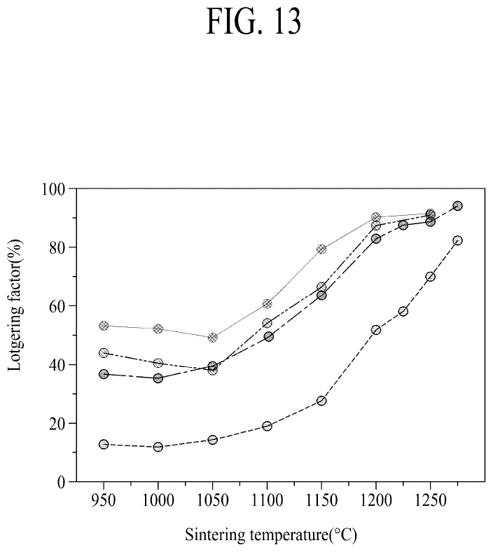

FIG. 15 illustrates an automotive sound apparatus according to an example embodiment of the present disclosure.

Referring to FIG. 15, a vehicular sound apparatus according to an example embodiment of the present disclosure may include a sound apparatus 500. The sound apparatus 500 may be disposed or equipped in a vehicle to output a sound S toward an internal space IS of a vehicle 800.

The vehicle 800 may include an interior material (or an interior finish material) 850. In the following description, for convenience of description, the “interior material 850” may be referred to as a “vehicular interior material 850”.

The vehicular interior material 850 may include all parts configuring the inside of the vehicle 800, or may include all parts disposed at the internal space IS of the vehicle 800. For example, the vehicular interior material 850 may be an interior member or an inner finishing member of the vehicle 800, but example embodiments of the present disclosure are not limited thereto.

The vehicular interior material 850 according to some example embodiments of the present disclosure may be configured to be exposed at the internal or interior space IS of the vehicle 800, in the internal or interior space IS of the vehicle 800. For example, the vehicular interior material 850 may be provided to cover one surface (or an interior surface) of at least one of a main frame (or a vehicular body), a side frame (or a side body), a door frame (or a door body), a handle frame (or a steering hub), and a seat frame, which are exposed at the interior space IS of the vehicle 800.

The vehicular interior material 850 according to some example embodiments of the present disclosure may include a dash board, a pillar interior material (or a pillar trim), a floor interior material (or a floor carpet), a roof interior material (or a headliner), a door interior material (or a door trim), a handle interior material (or a steering cover), a seat interior material, a rear package interior material (or a backseat shelf), an overhead console (or an interior illumination interior material), a rear view mirror, a glove box, and a sun visor, but example embodiments of the present disclosure are not limited thereto.

The vehicular interior material 850 according to some example embodiments of the present disclosure may include one or more of metal, wood, rubber, plastic, glass, fiber, cloth, paper, mirror, leather, and carbon, but example embodiments of the present disclosure are not limited thereto. The vehicular interior material 850 including a plastic material may be an injection material which is implemented by an injection process using thermosetting resin or thermoplastic resin, but example embodiments of the present disclosure are not limited thereto. The vehicular interior material 850 including a fiber material may include one or more of synthetic fiber, carbon fiber (or aramid fiber), and natural fiber, but example embodiments of the present disclosure are not limited thereto. The vehicular interior material 850 including a fiber material may include may be a fabric sheet, a knitting sheet, or a nonwoven fabric, but example embodiments of the present disclosure are not limited thereto. For example, the interior material 20c or the outer surface member including a fiber material may be a fabric member, but example embodiments of the present disclosure are not limited thereto. For example, the paper may be cone paper. For example, the cone paper may be pulp or foam plastic, but example embodiments of the present disclosure are not limited thereto. The vehicular interior material 850 including a leather material may include may be a natural leather or an artificial leather, but example embodiments of the present disclosure are not limited thereto.

The vehicular interior material 850 according to some example embodiments of the present disclosure may include one or more of a flat part and a curved part. For example, the vehicular interior material 850 may have a structure corresponding to a structure of a corresponding vehicular structure material, or may have a structure which differs from the structure of the corresponding vehicular structure material.

According to some example embodiments of the present disclosure, the sound apparatus 500 may be disposed at the vehicular interior material 850. The sound apparatus 500 may vibrate the vehicular interior material 850 to generate a sound S, based on a vibration of the vehicular interior material 850. For example, the sound apparatus 500 may directly vibrate the vehicular interior material 850 to generate the sound S, based on a vibration of the vehicular interior material 850.

For example, the sound apparatus 500 may be configured with one of the piezoelectric devices according to one or more example embodiments of the present disclosure described above with reference to FIGS. 1 to 14.

For example, the sound apparatus 500 may be configured to vibrate the vehicular interior material 850 to output the sound S toward the internal or interior space IS of the vehicle 800. Therefore, the vehicular interior material 850 may be used as a sound vibration plate. The vehicular interior material 850 may be a vibration plate, a sound vibration plate, or a sound generating plate for outputting the sound S. For example, the vehicular interior material 850 may have a size which is greater than that of the sound apparatus 500, but example embodiments of the present disclosure are not limited thereto.

For example, the sound apparatus 500 may be disposed at one or more of a dash board, a pillar interior material, a floor interior material, a roof interior material, a door interior material, a handle interior material, and a seat interior material, or may be disposed in one or more of a rear package interior material, an overhead console, a rear view mirror, a glove box, and a sun visor.

The sound apparatus 500 according to some example embodiments of the present disclosure may vibrate a correspond vehicular interior material 850 through at least one of one or more sound apparatuses 500 disposed at the vehicular interior material 850 to output a realistic sound S and/or stereo sound, including a multichannel, toward the interior space IS of the vehicle 800.

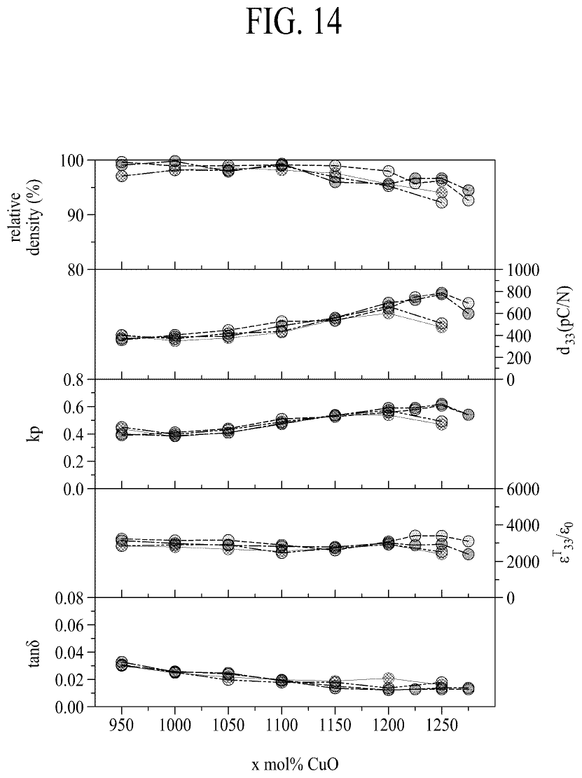

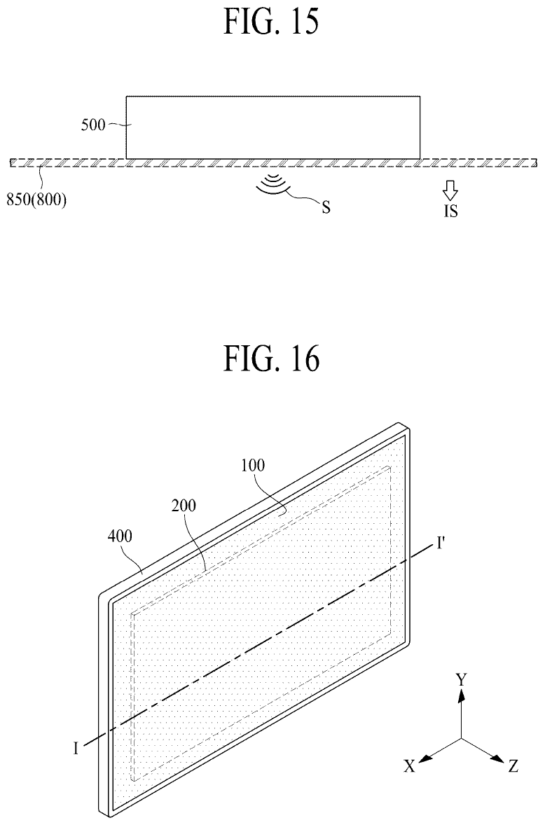

FIG. 16 illustrates a perspective view of a display apparatus according to an example embodiment of the present disclosure. FIG. 17 illustrates a cross-sectional view taken along line I-I′ in FIG. 16 according to an example embodiment of the present disclosure.

Referring to FIGS. 16 and 17, an apparatus according to an example embodiment of the present disclosure may include a vibration member 100 and a piezoelectric device 200.

The vibration member 100 may be configured to display an image. The piezoelectric device 200 may be disposed at a rear surface (or a backside) of the vibration member 100. For example, the piezoelectric device 200 may be configured to vibrate the vibration member 100.

For example, the vibration member 100 may output a sound based on a vibration of the piezoelectric device 200. For example, the vibration member 100 may be a vibration object, a display panel, a vibration plate, or a front member, but example embodiments of the present disclosure are not limited thereto.

For example, the vibration member 100 or the vibration object may include one or more among a display panel including a pixel configured to display an image, a screen panel on which an image is to be projected from a display apparatus, a lighting panel, a signage panel, a vehicular interior material, a vehicular glass window (or a vehicular window), a vehicular exterior material, a building ceiling material, a building interior material, a building glass window (or a building window), an aircraft interior material, an aircraft glass window (or an aircraft window), wood, plastic, glass, metal, cloth, fiber, paper, rubber, leather, and a mirror, but example embodiments of the present disclosure are not limited thereto.

In the following description, the vibration member 100 is a display panel 100 will be described.

The display panel 100 may display an electronic image, a digital image, a still image, or a video image. For example, the display panel 100 may output light to display an image. The display panel 100 may be a curved display panel, or may be any type of display panel, such as a liquid crystal display panel, an organic light emitting display panel, a quantum dot light emitting display panel, a micro light emitting diode display panel, and an electrophoresis display panel, or the like. The display panel 100 may be a flexible display panel. For example, the display panel 100 may a flexible light emitting display panel, a flexible electrophoretic display panel, a flexible electro-wetting display panel, a flexible micro light emitting diode display panel, or a flexible quantum dot light emitting display panel, but example embodiments of the present disclosure are not limited thereto.

The display panel 100 according to some example embodiments of the present disclosure may include a display area AA (or an active area) configured to display an image according to driving of the plurality of pixels. Also, the display panel 100 may further include a non-display area IA surrounding the display area AA, but example embodiments of the present disclosure are not limited thereto.

The piezoelectric device 200 may vibrate the display panel 100 at a rear surface of the display panel 100, thereby providing a sound and/or a haptic feedback based on a vibration of the display panel 100 to a user (or a viewer). The piezoelectric device 200 may be implemented at the rear surface of the display panel 100 to directly vibrate the display panel 100.

As some example embodiments of the present disclosure, the piezoelectric device 200 may vibrate according to a voice signal synchronized with an image displayed by the display panel 100 to vibrate the display panel 100. As another example embodiment of the present disclosure, the piezoelectric device 200 may be disposed at the display panel 100, or may vibrate according to a haptic feedback signal (or a tactile feedback signal) synchronized with a user touch applied to a touch panel (or a touch sensor layer) embedded into the display panel 100 to vibrate the display panel 100. Accordingly, the display panel 100 may vibrate based on a vibration of the piezoelectric device 200 to provide a user (or a viewer) with at least one of sound and a haptic feedback.

The piezoelectric device 200 according to some example embodiments of the present disclosure may be implemented to have a size corresponding to the display area AA of the display panel 100. A size of the piezoelectric device 200 may be 0.9 to 1.1 times a size of the display area AA, but example embodiments of the present disclosure are not limited thereto. For example, a size of the piezoelectric device 200 may be the same as or smaller than the size of the display area AA. For example, a size of the piezoelectric device 200 may be the same as or approximately same as the display area AA of the display panel 100, and thus, the piezoelectric device 200 may cover a most region of the display panel 100 and a vibration generated by the piezoelectric device 200 may vibrate an entire area of the display panel 100, and thus, localization of a sound may be high, and satisfaction of a user may be improved. Also, a contact area (or panel coverage) between the display panel 100 and the piezoelectric device 200 may increase, and thus, a vibration region of the display panel 100 may increase, thereby improving a sound of a middle-low-pitched sound band generated based on a vibration of the display panel 100. And, a piezoelectric device 200 applied to a large-sized display apparatus may vibrate the entire display panel 100 having a large size (or a large area), and thus, localization of a sound based on a vibration of the display panel 100 may be further enhanced, thereby realizing an improved sound effect. Therefore, the piezoelectric device 200 according to some example embodiments of the present disclosure may be disposed at the rear surface of the display panel 100 to sufficiently vibrate the display panel 100 in a vertical (or front-to-rear) direction, thereby outputting a desired sound to a forward region in front of the apparatus or the display apparatus.

The piezoelectric device 200 according to some example embodiments of the present disclosure may be implemented as a film type. Since the piezoelectric device 200 may be implemented as a film type, it may have a thickness which is thinner than the display panel 100, and thus, a thickness of the display apparatus may not increase due to the arrangement of the piezoelectric device 200. For example, the piezoelectric device 200 may use the display panel 100 as a sound vibration plate. For example, the piezoelectric device 200 may be referred to as a sound generating module, a vibration generating apparatus, a film actuator, a film type piezoelectric composite actuator, a film speaker, a film type piezoelectric speaker, or a film type piezoelectric composite speaker, which uses the display panel 100 as a vibration plate, but example embodiments of the present disclosure are not limited thereto. As another example embodiment of the present disclosure, the piezoelectric device 200 may not be disposed at the rear surface of the display panel 100 and may be applied to a vibration object instead of the display panel. For example, the vibration object may be one or more of a non-display panel, wood, metal, plastic, glass, cloth, paper, mirror, fiber, rubber, leather, a vehicle interior material, a vehicle glass window (or a vehicle window), a building indoor ceiling, a building glass window (or a building window), a building interior material, an aircraft interior material, and an aircraft glass window (or an aircraft window), or the like, but example embodiments of the present disclosure are not limited thereto. For example, the non-display panel may be a light emitting diode lighting panel (or apparatus), an organic light emitting lighting panel (or apparatus), or an inorganic light emitting lighting panel (or apparatus), or the like, but example embodiments of the present disclosure are not limited thereto. In this case, the vibration object may be applied as a vibration plate, and the piezoelectric device 200 may vibrate the vibration object to output a sound.

The piezoelectric device 200 according to some example embodiments of the present disclosure may further include a vibration structure 230, a connection member 210 disposed between the vibration structure 230 and the display panel 100.

According to some example embodiments of the present disclosure, the connection member 210 may include at least one substrate, and may include an adhesive layer attached to one surface or both surfaces of the substrate, or may be configured as a single layer of adhesive layer.

For example, the connection member 210 may include a foam pad, a double-sided foam pad, a double-sided tape, a double-sided foam tape, a double-sided adhesive, or an adhesive, or the like, but example embodiments of the present disclosure are not limited thereto. For example, the adhesive layer of the connection member 210 may include epoxy-based, acrylic-based, silicone-based, or urethane-based, but example embodiments of the present disclosure are not limited thereto.

The display panel 100 according to some example embodiments of the present disclosure may further include a supporting member 300 disposed at a rear surface of the display panel 100.

The supporting member 300 may cover a rear surface of the display panel 100. For example, the supporting member 300 may cover a whole rear surface of the display panel 100 with a gap space GS therebetween. For example, the supporting member 300 may include at least one or more among a glass material, a metal material, and a plastic material. For example, the supporting member 300 may be a rear structure or a set structure. For example, the supporting member 300 may be a cover bottom, a plate bottom, a back cover, a base frame, a metal frame, a metal chassis, a chassis base, or m-chassis, or the like, but example embodiments of the present disclosure are not limited thereto. Therefore, the supporting member 300 may be implemented as an arbitrary type frame or a plate-shaped structure disposed at a rear surface of the display panel 100.

The apparatus according to some example embodiments of the present disclosure may further include a middle frame 400.

The middle frame 400 may be disposed between a rear periphery of the display panel 100 and a front periphery of the supporting member 300. The middle frame 400 may support at least one or more among the rear periphery of the display panel 100 and the front periphery of the supporting member 300, respectively, and may surround one or more of side surfaces among each of the display panel 100 and the supporting member 300. The middle frame 400 may configure a gap space GS between the display panel 100 and the supporting member 300. The middle frame 400 may be referred to as a middle cabinet, a middle cover, a middle chassis, or the like, but example embodiments of the present disclosure are not limited thereto.

The middle frame 400 according to some example embodiments of the present disclosure may include a first supporting part 410 and a second supporting part 430.

The first supporting part 410 may be disposed between the rear periphery of the display panel 100 and the front periphery of the supporting member 300, and thus, may configure the gap space GS between the display panel 100 and the supporting member 300. A front surface of the first supporting part 410 may be coupled or connected to the rear periphery of the display panel 100 by a first frame connection member 401. A rear surface of the first supporting part 410 may be coupled or connected to the front periphery of the supporting member 300 by a second frame connection member 403. For example, the first supporting part 710 may have a single picture frame structure having a square shape or a frame structure having a plurality of divided bar shapes, but example embodiments of the present disclosure are not limited thereto.

The second supporting part 430 may be vertically coupled to an outer surface of the first supporting part 410 in parallel with a thickness direction Z of the apparatus. The second supporting part 430 may surround one or more among an outer surface of the display panel 100 and an outer surface of the supporting member 300, thereby protecting the outer surface of each of the display panel 100 and the supporting member 300. The first supporting part 410 may protrude from an inner surface of the second supporting part 430 toward the gap space GS between the display panel 100 and the supporting member 300.

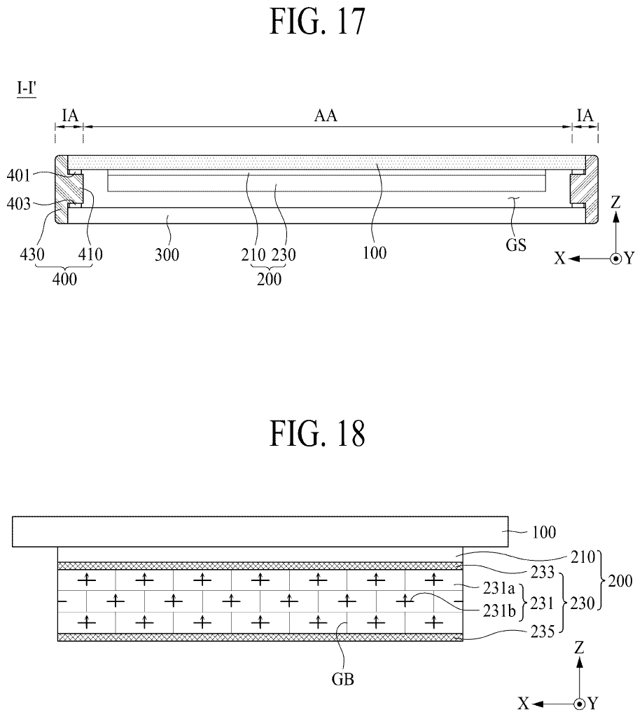

FIG. 18 illustrates a piezoelectric device in the example embodiment illustrated in FIG. 16 according to an example embodiment of the present disclosure.

Referring to FIG. 18, the piezoelectric device 200 according to an example embodiment of the present disclosure may include a vibration structure 230.

The vibration structure 230 may include a piezoelectric device layer 231, a first electrode 233, and a second electrode 235.

The vibration structure 230 may include a first electrode 233 disposed at a first surface of a piezoelectric device layer 231, and a second electrode 235 disposed at a second surface, which is opposite to (or different from) the first surface, of the piezoelectric device layer 231.

The piezoelectric device layer 231 may include a first material layer 231a and a second material layer 231b surrounded by the first material layer 231a. According to some example embodiments of the present disclosure, one first material layer 231a and one second material layer 231b may configure one grain having the same or substantially the same crystal direction, and a grain boundary GB may be formed at a portion where another first material layer 231a and second material layer 231b configuring another adjacent grain contact each other. In one or more example embodiments of the present disclosure, the crystal direction is +Z axis direction defined in the figures. However, example embodiments of the present disclosure are not limited thereto, and the crystal direction could also be various directions applicable.

According to some example embodiments of the present disclosure, a grain of the first material layer 231a may be grown based on a crystal direction of the second material layer 231b, and thus, a plurality of first material layers 231a may have the same or substantially the same crystal direction, and for example, may have a [001] crystal direction, but example embodiments of the present disclosure are not limited thereto.

According to some example embodiments of the present disclosure, the first electrode 233 may be disposed at the first surface of a piezoelectric device layer 231. The second electrode 235 may be disposed at the second surface, which is opposite to (or different from) the first surface, of the piezoelectric device layer 231.

The first electrode 233 and the second electrode 235 may use a metal electrode, and for example, a silver electrode may be used, but example embodiments of the present disclosure are not limited thereto.

Moreover, in FIG. 18, the vibration structure 230 is illustrated as a single layer, but may be configured to be additionally stacked based on the desired performance of a piezoelectric device.

The aspect of the vibration structure 230 described above has been described as an example. The vibration structure 230 according to some example embodiments of the present disclosure is not limited to a specific structure or configuration, such as the amount and/or location, or the like, of material layers.

A piezoelectric device according to some example embodiments of the present disclosure may be applied to (or included in) a vibration apparatus (or a sound apparatus) disposed at an apparatus. The apparatus according to some example embodiments of the present disclosure may be applied to mobile apparatuses, video phones, smart watches, watch phones, wearable apparatuses, foldable apparatuses, rollable apparatuses, bendable apparatuses, flexible apparatuses, curved apparatuses, sliding apparatuses, variable apparatuses, electronic organizers, electronic book, portable multimedia players (PMPs), personal digital assistants (PDAs), MP3 players, mobile medical devices, desktop personal computers (PCs), laptop PCs, netbook computers, workstations, navigation apparatuses, automotive navigation apparatuses, automotive display apparatuses, automotive apparatuses, theater apparatuses, theater display apparatuses, TVs, wall paper display apparatuses, signage apparatuses, game apparatuses, notebook computers, monitors, cameras, camcorders, home appliances, or the like. Addition, the vibration apparatus according to some example embodiments of the present disclosure may be applied to (or included in) organic light emitting lighting apparatuses or inorganic light emitting lighting apparatuses. When the vibration apparatus is applied to (or included in) lighting apparatuses, the lighting apparatuses may act as lighting and a speaker. Addition, when the vibration apparatus of the present disclosure is applied to (or included in) a mobile apparatus, or the like, the vibration apparatus may act as one or more of a speaker, a receiver, and a haptic device, but example embodiments of the present disclosure are not limited thereto.

A piezoelectric material composition, a method of manufacturing the same, a piezoelectric device, and an apparatus including the piezoelectric device according to one or more aspect of the present disclosure are described below. Example embodiments of the present disclosure can also be described as follows.

A piezoelectric material composition according to an aspect of the present disclosure may be represented by Equation 1.

$${aPbZrO}_{3} - {bPbTiO}_{3} - ( 1 - a - b ) Pb ( {Ni}_{c} {Nb}_{1 - c} ) {O}_{3} + x mol \% A + y vol \% {BaTiO}_{3} \qquad [ Equation 1 ]$$

where A is Fe₂O₃, Co₂O₃, Mn₂O₃, ZnO, GeO₂, CuO, or NiO, and 0.15≤a≤0.24, 0.29≤b≤0.38, 0.30≤c≤0.35, 0.00≤x≤3.00, and 0.00≤y≤7.00.

According to one or more example embodiments of the present disclosure, the piezoelectric material composition may comprise a first portion, and a second portion surrounded by the first portion.

According to one or more example embodiments of the present disclosure, the first portion may include a first material that may be represented by Equation 2.

$${aPbZrO}_{3} - {bPbTiO}_{3} - ( 1 - a - b ) Pb ( {Ni}_{c} {Nb}_{1 - c} ) {O}_{3} + x mol \% A \qquad [ Equation 2 ]$$

where A is Fe₂O₃, Co₂O₃, Mn₂O₃, ZnO, GeO₂, CuO, or NiO, and

0.15≤a≤0.24, 0.29≤b≤0.38, 0.30≤c≤0.35, and 0.00≤x≤3.00.

According to one or more example embodiments of the present disclosure, the piezoelectric material composition may have a piezoelectric charge constant of 400 pC/N to 1,000 pC/N.

According to one or more example embodiments of the present disclosure, the first portion may include a first material. The first material may comprise CuO to satisfy 0.00<x≤3.00, with respect to the piezoelectric material composition.

According to one or more example embodiments of the present disclosure, the second portion may include a second material. The second material may comprise BaTiO₃ to satisfy 0.00<y≤7.00, with respect to the piezoelectric material composition.

According to one or more example embodiments of the present disclosure, the piezoelectric material composition may comprise a plurality of grains oriented in a (001) single orientation. The second portion may include a second material that may be disposed in the plurality of grains. The plurality of grains may be grown from the second material.

According to one or more example embodiments of the present disclosure, the piezoelectric material composition may have a Lotgering factor of 70% or more.

According to one or more example embodiments of the present disclosure, the piezoelectric material composition may have a relative density of 90% or more.

According to one or more example embodiments of the present disclosure, the first portion includes a first material represented by Equation 2:

$${aPbZrO}_{3} - {bPbTiO}_{3} - ( 1 - a - b ) Pb ( {Ni}_{c} {Nb}_{1 - c} ) {O}_{3} + x mol \% A \qquad [ Equation 2 ]$$

where A is Fe₂O₃, Co₂O₃, Mn₂O₃, ZnO, GeO₂, CuO, or NiO, and 0.15≤a≤0.24, 0.29≤b≤0.38, 0.30≤c≤0.35, and 0.00≤x≤3.00. The second portion may include a second material. The second material may include BaTiO₃ to satisfy 0.00<y≤7.00, with respect to the piezoelectric material composition.

A method of manufacturing a piezoelectric material composition according to another aspect of the present disclosure may comprise mixing a matrix material with a seed material to prepare a slurry, molding the slurry to prepare a green tape, and sintering the green tape to prepare a sinter that includes the piezoelectric material composition. The piezoelectric material composition may be represented by Equation 1.

$${aPbZrO}_{3} - {bPbTiO}_{3} - ( 1 - a - b ) Pb ( {Ni}_{c} {Nb}_{1 - c} ) {O}_{3} + x mol \% A + y vol \% {BaTiO}_{3} \qquad [ Equation 1 ]$$

where A is Fe₂O₃, Co₂O₃, Mn₂O₃, ZnO, GeO₂, CuO, or NiO, and 0.15≤a≤0.24, 0.29≤b≤0.38, 0.30≤c≤0.35, 0.00≤x≤3.00, and 0.00≤y≤7.00.

According to one or more example embodiments of the present disclosure, the matrix material may be represented by Equation 2.

$${aPbZrO}_{3} - {bPbTiO}_{3} - ( 1 - a - b ) Pb ( {Ni}_{c} {Nb}_{1 - c} ) {O}_{3} + x mol \% A \qquad [ Equation 2 ]$$

where 0.15≤a≤0.24, 0.29≤b≤0.38, 0.30≤c≤0.35, and 0.00≤x≤3.00.

According to one or more example embodiments of the present disclosure, the seed material may comprise BaTiO₃.

According to one or more example embodiments of the present disclosure, the seed material may be added to satisfy 0.00<y≤7.00, with respect to the piezoelectric material composition.

According to one or more example embodiments of the present disclosure, the sintering of the green tape to prepare the sinter may be performed for 9 hours to 10 hours at a temperature of 950° C. to 1,250° C.

A piezoelectric device according to yet another aspect of the present disclosure may comprise a piezoelectric device layer including a piezoelectric material composition including a first material and a second material surrounded by the first material, a first electrode disposed at a first surface of the piezoelectric device layer, and a second electrode disposed at a second surface different from the first surface of the piezoelectric device layer. The piezoelectric material composition may be represented by Equation 1.

$${aPbZrO}_{3} - {bPbTiO}_{3} - ( 1 - a - b ) Pb ( {Ni}_{c} {Nb}_{1 - c} ) {O}_{3} + x mol \% A + y vol \% {BaTiO}_{3} \qquad [ Equation 1 ]$$

A is Fe₂O₃, Co₂O₃, Mn₂O₃, ZnO, GeO₂, CuO, or NiO, and 0.15≤a≤0.4, 0.29≤b≤0.38, 0.30≤c≤0.35, 0.00≤x≤3.00, and 0.00≤y≤7.00.

According to one or more example embodiments of the present disclosure, the first material may comprise CuO to satisfy 0.00<x≤3.00, with respect to the piezoelectric material composition.

According to one or more example embodiments of the present disclosure, the second material may comprise BaTiO₃ to satisfy 0.00<y≤7.00, with respect to the piezoelectric material composition.

An apparatus according to still another aspect of the present disclosure may comprise a vibration member, and the piezoelectric device disposed at a rear surface of the vibration member. The piezoelectric device may comprise a piezoelectric device layer including a first material and a second material surrounded by the first material, a first electrode disposed at a first surface of the piezoelectric device layer, and a second electrode disposed at a second surface different from the first surface of the piezoelectric device layer. The piezoelectric material composition may be represented by Equation 1.

$${aPbZrO}_{3} - {bPbTiO}_{3} - ( 1 - a - b ) Pb ( {Ni}_{c} {Nb}_{1 - c} ) {O}_{3} + x mol \% A + y vol \% {BaTiO}_{3} \qquad [ Equation 1 ]$$

where A is Fe₂O₃, Co₂O₃, Mn₂O₃, ZnO, GeO₂, CuO, or NiO, and 0.15≤a≤0.24, 0.29≤b≤0.38, 0.30≤c≤0.35, 0.00≤x≤3.00, and 0.00≤y≤7.00.

According to one or more example embodiments of the present disclosure, the vibration member may comprise one or more of a display panel including a plurality of pixels configured to display an image, a screen panel on which an image is to be projected from a display apparatus, a light emitting diode lighting panel, an organic light emitting lighting panel, an inorganic light emitting lighting panel, a signage panel, an interior material of a vehicle, an exterior material of a vehicular vehicle, a window (or a glass window) of a vehicle, a seat interior material of a vehicle, a ceiling material of a building, an interior material of a building, a window (or a glass window) of a building, an interior material of an aircraft, a window (or a glass window) of an aircraft, wood, plastic, glass, metal, cloth, fiber, paper, rubber, leather, carbon, and a mirror.

It will be apparent to those skilled in the art that various modifications and variations can be made in the present disclosure without departing from the scope of the disclosure. Thus, it is intended that the present disclosure covers the modifications and variations of this disclosure that come within the scope of the appended claims and their equivalents.

What is claimed is:

1. A piezoelectric material composition represented by Equation 1,
aPbZrO₃-bPbTiO₃-(1-a-b)Pb(Ni_{c}Nb_{1-c})O₃+x mol % A+y vol % BaTiO₃ [Equation 1]
wherein:
A is Fe₂O₃, Co₂O₃, Mn₂O₃, ZnO, GeO₂, CuO, or NiO,
0.15≤a≤0.24,
0.29≤b≤0.38,
0.30≤c≤0.35,
0.00≤x≤3.00, and
0.00≤y≤7.00.

2. The piezoelectric material composition of claim 1, comprising:
a first portion; and
a second portion surrounded by the first portion.

3. The piezoelectric material composition of claim 2, wherein the first portion includes a first material represented by Equation 2,
$${aPbZrO}_{3} - {bPbTiO}_{3} - ( 1 - a - b ) Pb ( {Ni}_{c} {Nb}_{1 - c} ) {O}_{3} + x mol \% A \qquad [ Equation 2 ]$$
wherein:
A is Fe₂O₃, Co₂O₃, Mn₂O₃, ZnO, GeO₂, CuO, or NiO,
0.15≤a≤0.24,
0.29≤b≤0.38,
0.30≤c≤0.35, and
0.00≤x≤3.00.

4. The piezoelectric material composition of claim 1, wherein the piezoelectric material composition has a piezoelectric charge constant of 400 pC/N to 1,000 pC/N.

5. The piezoelectric material composition of claim 2, wherein the first portion includes a first material, and
wherein the first material comprises CuO to satisfy 0.00<x≤3.00, with respect to the piezoelectric material composition.

6. The piezoelectric material composition of claim 2, wherein the second portion includes a second material, and
wherein the second material comprises BaTiO₃ to satisfy 0.00<y≤7.00, with respect to the piezoelectric material composition.

7. The piezoelectric material composition of claim 2, wherein the piezoelectric material composition comprises a plurality of grains oriented in a (001) single orientation,
wherein the second portion includes a second material that is disposed in the plurality of grains, and
wherein the plurality of grains are grown from the second material.

8. The piezoelectric material composition of claim 1, wherein the piezoelectric material composition has a Lotgering factor of 70% or more.

9. The piezoelectric material composition of claim 1, wherein the piezoelectric material composition has a relative density of 90% or more.

10. The piezoelectric material composition of claim 2, wherein the first portion includes a first material represented by Equation 2,
$${aPbZrO}_{3} - {bPbTiO}_{3} - ( 1 - a - b ) Pb ( {Ni}_{c} {Nb}_{1 - c} ) {O}_{3} + x mol \% A \qquad [ Equation 2 ]$$
wherein:
A is Fe₂O₃, Co₂O₃, Mn₂O₃, ZnO, GeO₂, CuO, or NiO,
0.15≤a≤0.24,
0.29≤b≤0.38,
0.30≤c≤0.35, and
0.00≤x≤3.00,
wherein the second portion includes a second material, and
wherein the second material comprises BaTiO₃ to satisfy 0.00<y≤7.00, with respect to the piezoelectric material composition.

11. A method of manufacturing a piezoelectric material composition, the method comprising:
mixing a matrix material with a seed material to prepare a slurry;
molding the slurry to prepare a green tape; and
sintering the green tape to prepare a sinter that includes the piezoelectric material composition,
wherein the piezoelectric material composition is represented by Equation 1,
$${aPbZrO}_{3} - {bPbTiO}_{3} - ( 1 - a - b ) Pb ( {Ni}_{c} {Nb}_{1 - c} ) {O}_{3} + x mol \% A + y vol \% {BaTiO}_{3} \qquad [ Equation 1 ]$$
where:
A is Fe₂O₃, Co₂O₃, Mn₂O₃, ZnO, GeO₂, CuO, or NiO,
0.15≤a≤0.24,
0.29≤b≤0.38,
0.30≤c≤0.35,
0.00≤x≤3.00, and
0.00≤y≤7.00.

12. The method of claim 11, wherein the matrix material is represented by Equation 2,
$${aPbZrO}_{3} - {bPbTiO}_{3} - ( 1 - a - b ) Pb ( {Ni}_{c} {Nb}_{1 - c} ) {O}_{3} + x mol \% A \qquad [ Equation 2 ]$$
where:
0.15≤a≤0.24,
0.29≤b≤0.38,
0.30≤c≤0.35, and
0.00≤x≤3.00.

13. The method of claim 11, wherein the seed material comprises BaTiO₃.

14. The method of claim 12, wherein the seed material is added to satisfy 0.00<y≤7.00, with respect to the piezoelectric material composition.

15. The method of claim 11, wherein the sintering of the green tape to prepare the sinter is performed for 9 hours to 10 hours at a temperature of 950° C. to 1,250° C.

16. A piezoelectric device, comprising:
a piezoelectric device layer including a piezoelectric material composition including a first material and a second material surrounded by the first material;
a first electrode disposed at a first surface of the piezoelectric device layer; and
a second electrode disposed at a second surface different from the first surface of the piezoelectric device layer,
wherein the piezoelectric material composition is represented by Equation 1,
$${aPbZrO}_{3} - {bPbTiO}_{3} - ( 1 - a - b ) Pb ( {Ni}_{c} {Nb}_{1 - c} ) {O}_{3} + x mol \% A + y vol \% {BaTiO}_{3} \qquad [ Equation 1 ]$$
where:
A is Fe₂O₃, Co₂O₃, Mn₂O₃, ZnO, GeO₂, CuO, or NiO,
0.15≤a≤0.24,
0.29≤b≤0.38,
0.30≤c≤0.35,
0.00≤x≤3.00, and
0.00≤y≤7.00.

17. The piezoelectric device of claim 16, wherein the first material comprises CuO to satisfy 0.00<x≤3.00, with respect to the piezoelectric material composition.

18. The piezoelectric device of claim 16, wherein the second material comprises BaTiO₃ to satisfy 0.00<y≤7.00, with respect to the piezoelectric material composition.

19. An apparatus, comprising:
a vibration member; and
the piezoelectric device of claim 16, the piezoelectric device being disposed at a rear surface of the vibration member.

20. The apparatus of claim 19, wherein the vibration member comprises one or more of:
a display panel including a plurality of pixels configured to display an image,
a screen panel on which an image is to be projected from a display apparatus,
a light emitting diode lighting panel,
an organic light emitting lighting panel,
an inorganic light emitting lighting panel,
a signage panel,
an interior material of a vehicle,
an exterior material of a vehicle,
a window of a vehicle,
a seat interior material of a vehicle,
a ceiling material of a building,
an interior material of a building,
a window of a building,
an interior material of an aircraft,
a window of an aircraft,
wood,
plastic,
glass,
metal,
cloth,
fiber,
paper,
rubber,
leather,
carbon, and
a mirror.
